(19) United States
(12) Patent Application Publication
(10) Pub. No.: US 2026/0344027 A1
(43) Pub. Date: Oct. 29, 2026

(54) SEMICONDUCTOR STRUCTURE AND METHOD FOR FORMING THE SAME

(71) Applicant: Taiwan Semiconductor Manufacturing Co., Ltd., Hsinchu (TW)

(72) Inventors: I-Han HUANG, Hsinchu (TW); Chu-Yuan HSU, Hsinchu (TW); Jia-Chuan YOU, Hsinchu (TW); Chia-Hao CHANG, Hsinchu (TW); Kuo-Cheng CHIANG, Hsinchu (TW)

(73) Assignee: Taiwan Semiconductor Manufacturing Co., Ltd., Hsinchu (TW)

(21) Appl. No.: 19/300,384

(22) Filed: Aug. 14, 2025

Related U.S. Application Data
(60) Provisional application No. 63/795,885, filed on Apr. 28, 2025.

(51) Int. Cl. H10D 84/83; H10D 30/00; H10D 30/01; H10D 30/43; H10D 62/10; H10D 62/13; H10D 64/66; H10D 84/01

(52) U.S. Cl. CPC H10D 84/832; H10D 30/014; H10D 30/0191; H10D 30/43; H10D 30/502; H10D 62/102; H10D 62/121; H10D 62/151; H10D 64/666; H10D 84/0135; H10D 84/0151

(57) ABSTRACT

An integrated circuit includes active regions separated from each other by isolation structures. Dielectric isolation structures are formed as gate metal cut regions and source/drain cut regions. The cuts in the gate metals and the source/drain regions are formed in a same etching process. Prior to the etching process, a cap feature is deposited at selected locations on the gate metal to prevent the etching process from cutting the gate metal at those locations. Dielectric isolation structures are then formed at the gate cut regions and the source/drain cut regions in a same process.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-23 are cross-sectional and top views of an integrated circuit at various stages of processing, in accordance with some embodiments.

FIG. 24 is a flow diagram of a method of manufacturing an integrated circuit, in accordance with some embodiments.

FIG. 25 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

The GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure enable formation of an array of transistors including efficiently and effectively isolating the source/drain regions of adjacent transistors and isolating the gate electrodes of adjacent transistors. After formation of the source/drain regions and gate metals of the transistors, dielectric isolation structures are formed to separate adjacent portions of the gate metal (at gate cut locations) and to separate adjacent source/drain regions of different transistors (at source/drain cut locations) in a same cut/isolation process. Prior to this process, a cap feature is formed on the gate metal at selected locations where the gate is not to be cut. After formation of the cap feature, the cut/isolation process includes an etching process that etches the source/drain regions and gate metals at desired locations, while the gate metal is protected at other locations by the cap feature. The cut/isolation process includes forming the dielectric isolation structures that extend through the cut locations. This enables further downward scaling of the distance between adjacent active regions. Wafer yields and device performances are improved with a simple and effective process.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

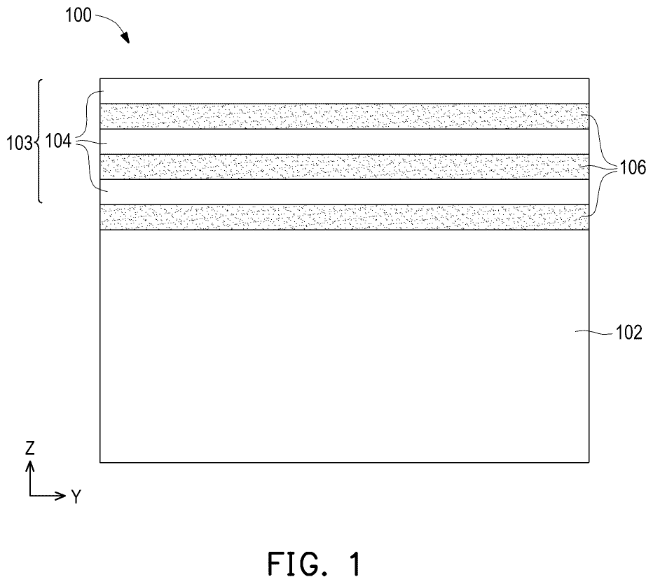

FIGS. 1-18 are cross-sectional and top views of an integrated circuit 100 fabricated in accordance with some embodiments of the present disclosure. The fabrication process results in a plurality of transistors 101, as will be described in further detail below.

FIG. 1 is a cross-sectional view of the integrated circuit 100 at an intermediate stage of processing. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. In the example of FIG. 1 the stack 103 includes three semiconductor layers 104 and three sacrificial semiconductor layers 106. However, in practice, different numbers of semiconductor layers 104 and sacrificial semiconductor layers 106 can be utilized without departing from the scope of the present disclosure.

As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In

In some embodiments, the semiconductor layers 104 may be formed of a first semiconductor material, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

In one example, the semiconductor layers 104 are silicon and the sacrificial semiconductor layers 106 are silicon germanium. In some embodiments, the sacrificial semiconductor layers 106 have a concentration of germanium between 10% and 50%, though other concentrations can be utilized without departing from the scope of the present disclosure. This enables the sacrificial semiconductor layers 106 to be selectively etchable with respect to the semiconductor layers 104. Other materials and concentrations can be utilized without departing from the scope of the present disclosure.

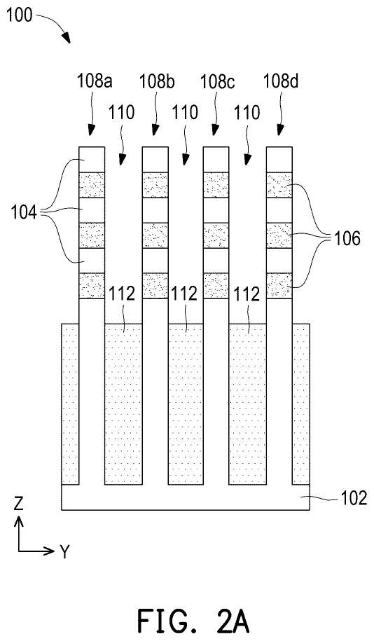

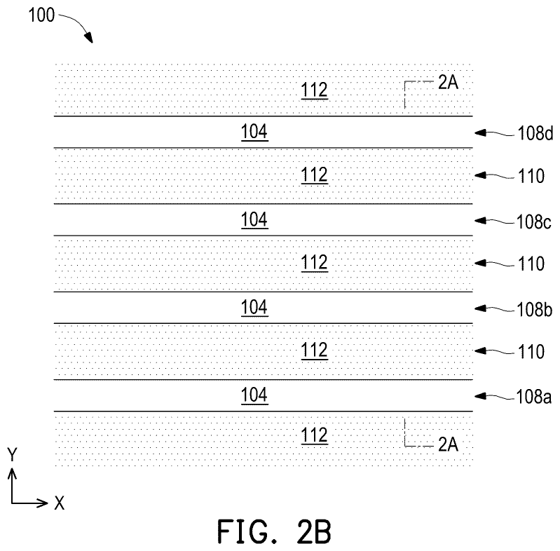

FIG. 2A is a cross-sectional view of the integrated circuit 100, in accordance with some embodiments. FIG. 2B is a top view of the integrated circuit 100 at the stage of processing shown in FIG. 2A, in accordance with some embodiments. The cross-sectional view of FIG. 2A is taken along cut lines 2A from FIG. 2B.

In FIG. 2A, a plurality of semiconductor fins 108a-d have been formed from the stack 103. In the following discussion, some reference numbers include a suffix “a”, “b”, “c”, or “d”. The suffixes may be omitted when reference is not particular to a specific single structure. For example, the semiconductor fins 108a-d may be referred to as simply semiconductor fins 108 when reference is generic to each of the semiconductor fins.

The semiconductor fins 108 are formed by forming trenches 110 in the stack 103 and in the substrate 102. Though not shown in FIG. 1, a hard mask layer is first formed and patterned on the stack 103. The trenches 110 are be formed with an anisotropic etching process that etches in the downward direction in the presence of the patterned hard mask. The etching process defines semiconductor fins 108 by forming trenches 110 through the sacrificial semiconductor layers 106, the semiconductor layers 104, and the substrate 102. The semiconductor fins 108 extend in the X direction and are separated from each other in the Y direction by the trenches 110.

The semiconductor fins 108 each correspond to an active area or an active region of the integrated circuit 100. Each active region corresponds to location in which the source/drain and channel regions of transistors are formed. The semiconductor fin 108a corresponds to a first active region. The semiconductor fin 108b corresponds to a second active region. The semiconductor fin 108c corresponds to a third active region. The semiconductor fin 108d corresponds to a fourth active region. In some embodiments, the substrate 102 of each semiconductor fin corresponds to a doped well region.

In some embodiments, each semiconductor fin 10a corresponds to a region of P-type transistors or a region of N-type transistors. In a particular example given herein, the semiconductor fins 108a and 108b correspond to regions at which P-type transistors are formed and the semiconductor fins 108c and 108d corresponds to regions at which N-type transistors are formed. Other distributions of P-type and N-type transistors can be utilized without departing from the scope of the present disclosure.

In FIGS. 2A and 2B, shallow isolation structures 112 have been formed by depositing a dielectric material in the trenches 110 between fins 108. FIG. 2A illustrates the shallow isolation structures 112 as a single layer of dielectric material. However, in practice, a plurality of dielectric layers can be utilized to form the isolation structures 112. The dielectric layer(s) may be deposited by chemical vapor deposition (CVD), atomic layer deposition (ALD), physical vapor deposition (PVD), or other suitable deposition processes. In an exemplary embodiment, the dielectric material of the isolation structures 112 includes silicon oxide. However, the dielectric material can include SiN, SiCN, SiOC, SiOCN, or other dielectric materials without departing from the scope of the present disclosure.

After deposition of the dielectric material of the isolation structure 112, an etch-back process has been performed to recess the top of the shallow isolation structures 112 below the lowest sacrificial semiconductor layers 106. This results in the shallow isolation structures 112 having a top surface that is lower than the bottom surface of the lowest sacrificial semiconductor layer 106 of each fin. Other processes can be utilized to form the shallow isolation structures 112 without departing from the scope of the present disclosure. Each isolation structure 112 extends in the X direction alongside and between two adjacent semiconductor fins 108.

In some embodiments, the isolation structures 112 include SiO2, an oxide formed from tetraethyl orthosilicate (TEOS), or other suitable dielectric materials. In some embodiments, the isolation structures 112 have a depth between 50 nm and 100 nm.

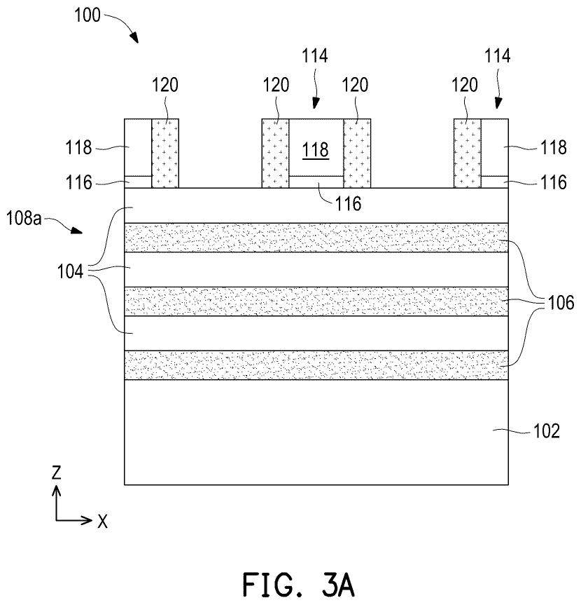

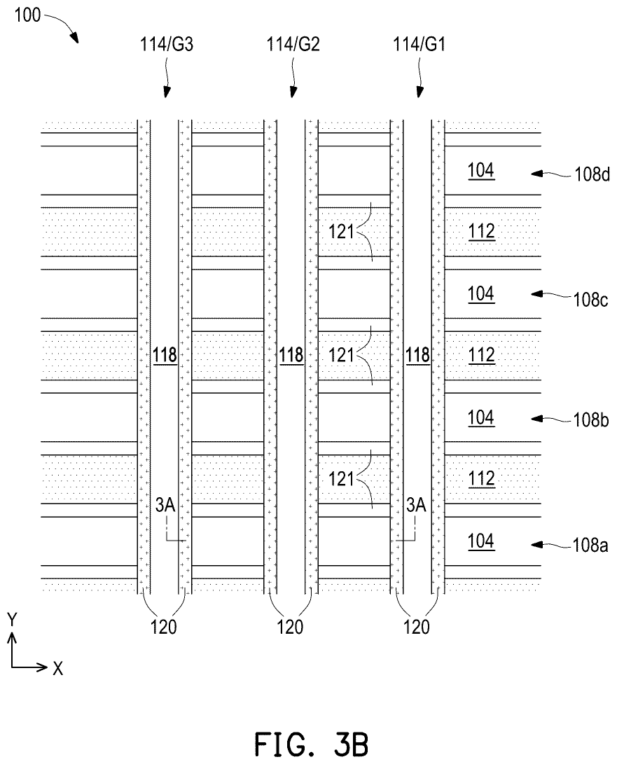

FIG. 3A is a cross-sectional view of the integrated circuit 100, in accordance with some embodiments. FIG. 3B is a top view of the integrated circuit 100 at the stage of processing shown in FIG. 3A. The cross-sectional view of FIG. 3A is taken along cut lines 3A from FIG. 3B.

In FIGS. 3A and 3B, sacrificial gate structures 114 have been formed over the fins 108. Each sacrificial gate structure 114 extends in the Y direction across the semiconductor fins 108 and the isolation structures 112. The layout of the sacrificial gate structures 114 corresponds to the layout of gate metals or gate structures of the transistors. In particular, the sacrificial gate structures 114 will eventually be replaced with gate metals. As will be set forth in more detail below, an efficient process will be utilized to cut the gate metals at selected locations between semiconductor fins 108 in order to electrically isolate the gate metals of adjacent transistors, in accordance with a circuit layout of the integrated circuit 100. The sacrificial gate structure 114 corresponds to a respective gate metal layout location G1-G3.

The sacrificial gate structures 114 include a dielectric layer 116. In an exemplary embodiment, the dielectric layer 116 includes silicon oxide. However, alternatively, the dielectric layer 116 can include SiN, SiCN, SiOC, SiOCN, or other dielectric materials without departing from the scope of the present disclosure. In some embodiments, the dielectric layer 116 has a low-K dielectric material. The dielectric layer 116 can be deposited by CVD, ALD, or PVD.

The sacrificial gate structures include a sacrificial gate layer 118 on the dielectric layer 116. The sacrificial gate layer 118 can include materials that have a high etch selectivity with respect to the isolation structures 112. In an exemplary embodiment, the sacrificial gate layer 118 includes polysilicon. However, the sacrificial gate layer 118 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 118 may be deposited by physical vapor deposition (PVD), CVD, sputter deposition, or other techniques for depositing the selected material.

In some embodiments, sacrificial gate structures 114 include a dielectric layer on the sacrificial gate layer 118. In an exemplary embodiment, the dielectric layer includes SiN. However, alternatively, the dielectric layer can include SiO, SiCN, SiOC, SiOCN, or other dielectric materials without departing from the scope of the present disclosure. The dielectric layer can be deposited by CVD, ALD, or PVD.

In FIGS. 3A and 3B, gate spacer layers 120 been formed on the sidewalls of the sacrificial gate structures 114. In particular, the gate spacer layer 120 is formed on sidewalls of the dielectric layer 116 and the sacrificial gate layer 118. The gate spacer layer 120 is also formed on top surfaces of the sacrificial gate structures 114, the top semiconductor layer 104 of each semiconductor fin 108, and other exposed surfaces. The gate spacer layer 120 can be formed by PVD, CVD, ALD, or other suitable deposition processes. In a particular example illustrated herein, the gate spacer layer 120 includes SiOCN. Alternatively, the gate spacer layer 120 can include one or more of SiO, SiN, SiON, SiCN, SiOC, or other suitable dielectric materials. In some embodiments, the gate spacer layer 120 has a width between 2 nm and 8 nm, though other thicknesses can be utilized without departing from the scope of the present disclosure.

In FIGS. 3A and 3B, an etching process has been performed to pattern the gate spacer layer 120. The etching process includes an anisotropic etching process that etches in the downward direction. The anisotropic etching process removes the gate spacer layer 120 from horizontal surfaces where the vertical thickness of the gate spacer 120 is small. After patterning of the gate spacer layers, vertically thicker portions of the gate spacer layer 120 remain on sidewalls of the sacrificial gate structures 114.

As can be seen in the top view of FIG. 3B dielectric structures 121 remain on the top surface of the isolation structures 112 as remnants of the gate spacer layer 120 after patterning of the gate spacer layer 120. As will be set forth in more detail below, these dielectric structures 121 will restrain the lateral growth of lower portions of source/drain regions.

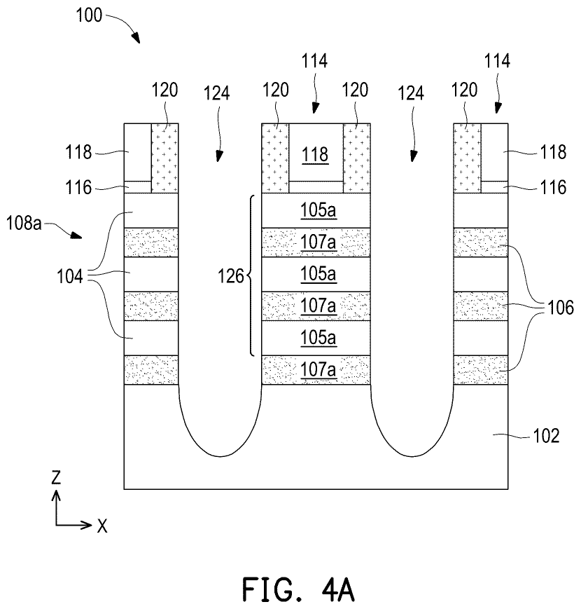

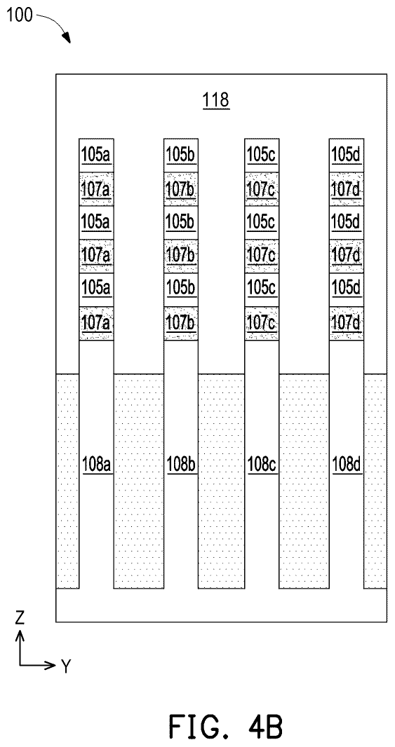

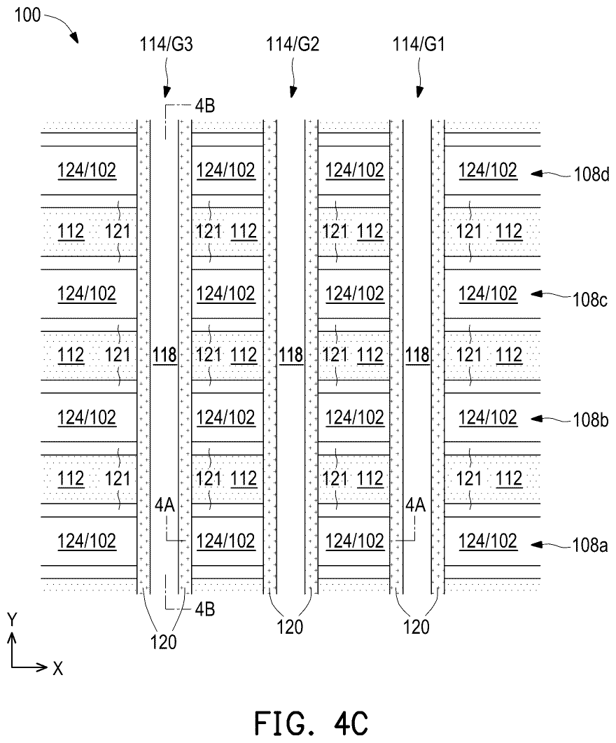

FIG. 4A is a cross-sectional view of the integrated circuit 100, in accordance with some embodiments. FIG. 4B is a cross-sectional view of the integrated circuit 100, in accordance with some embodiments. FIG. 4C is a top view of the integrated circuit 100 at the stage of processing shown in FIG. 4A. The cross-sectional view of FIG. 4A is taken along cut lines 4A from FIG. 4C. The cross-sectional view of FIG. 4B is taken along cut lines 4B from FIG. 4C.

In FIGS. 4A-4C, source/drain trenches 124 have been formed, in accordance with some embodiments. After patterning of the gate spacer layer 120, one or more etching processes are performed to form source/drain trenches 124 in the fins 108. Forming the source/drain trenches 124 includes etching through each of the semiconductor layers 104, each of the sacrificial semiconductor layers 106, and a portion of the substrate 102. Accordingly, the removal operations may include suitable etching operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 124 results in formation of stacks 126 of channels 105. In particular, the remaining portions of the semiconductor layers 104 after formation of the source/drain trenches 124 now correspond to stacked channels 105 of a transistor. Formation of the source/drain trenches 124 results in formation of a plurality of sacrificial semiconductor nanostructures 107 from the sacrificial semiconductor layers 106. The substrate 102 is exposed at the bottom of each source/drain trench 124. Each stack 126 of channels 105 corresponds to stacked channels of an individual transistor, as will be set forth in more detail below.

The semiconductor fin 108a includes stacked channels 105a and sacrificial semiconductor nanostructures 107a. The semiconductor fin 108b includes stacked channels 105b and sacrificial semiconductor nanostructures 107b. The semiconductor fin 108c includes stacked channels 105c and sacrificial semiconductor nanostructures 107c. The semiconductor fin 108d includes stacked channels 105d and sacrificial semiconductor nanostructures 107d.

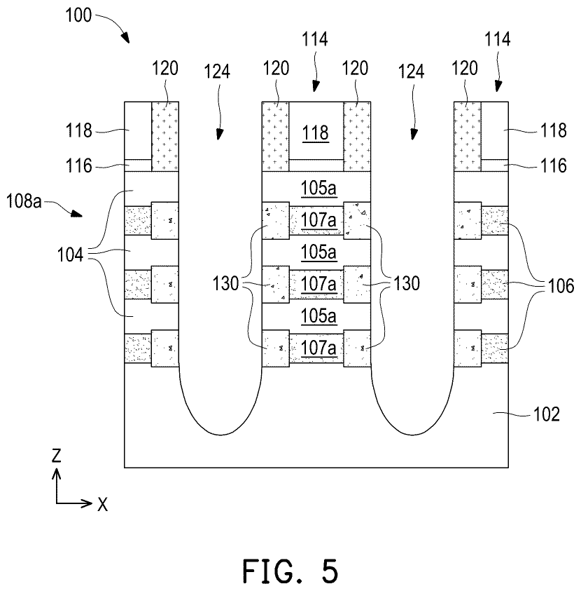

FIG. 5 is a cross-sectional view of the integrated circuit 100, in accordance with some embodiments. In FIG. 5, a selective etching process has been performed to recess exposed end portions of the sacrificial semiconductor nanostructures 107 without substantially etching the channels 105. More particularly, recesses are formed in the end portions of the sacrificial semiconductor nanostructures 107 relative to adjacent channels 105. The recesses can be formed by performing an etching process that selectively etches the material of the sacrificial semiconductor nanostructures 107 with respect to the material of the channels 105 and the substrate 102.

In FIG. 5, inner spacers 130 have been formed in the recesses. The inner spacers 130 are formed by depositing a dielectric layer in a conformal deposition process on exposed surfaces of the channels 105, the gate spacer layer 120, the sacrificial semiconductor nanostructures 107, and the substrate 102. Most notably, the dielectric layer fills the recesses. The dielectric layer can include SiCN, SiOCN, SiON, SiN, or other suitable dielectric materials. The dielectric layer can be formed by a suitable deposition method such as CVD, ALD, PVD, or other deposition processes.

Formation of the inner spacers 130 is completed by performing an anisotropic etching process that etches in the downward direction. During the anisotropic etching process, the gate spacer layer 120 and the sacrificial gate structures 114 function as a mask. The dielectric layer is removed from all locations exposed by the mask. The result is that the dielectric layer is removed from the trenches 124. The portion of the dielectric layer remaining in the recesses corresponds to the inner spacers 130. The inner spacers 130 are in contact with ends of the sacrificial semiconductor nanostructures 107 and with the channels 105. As will be set forth in further detail below, the inner spacers 130 will separate gate metals from source/drain regions.

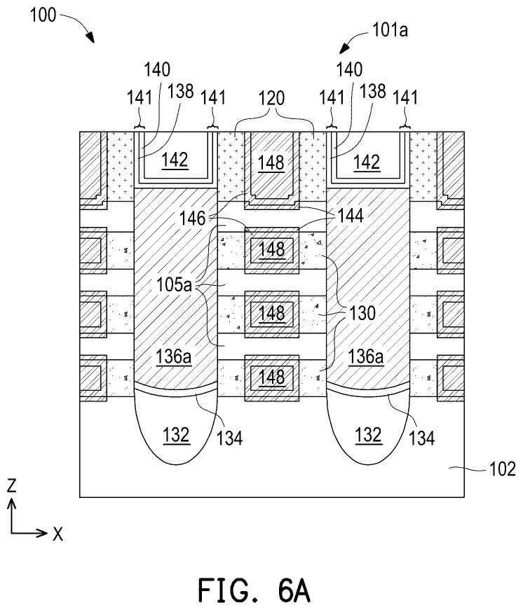

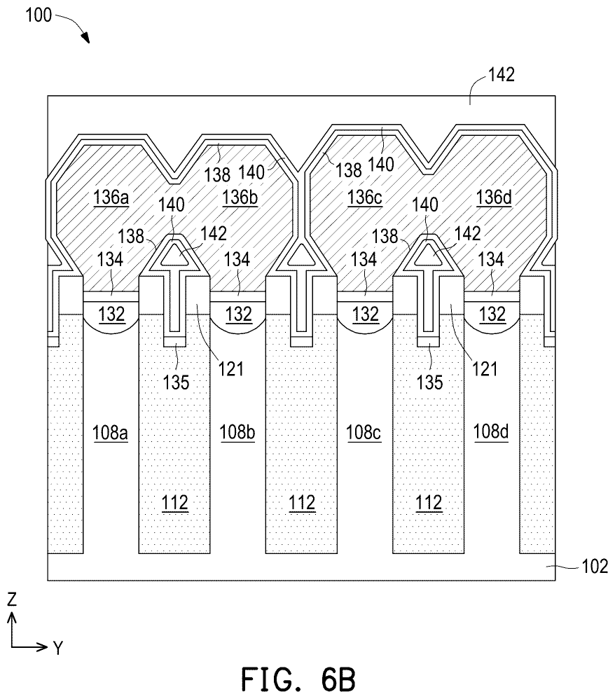

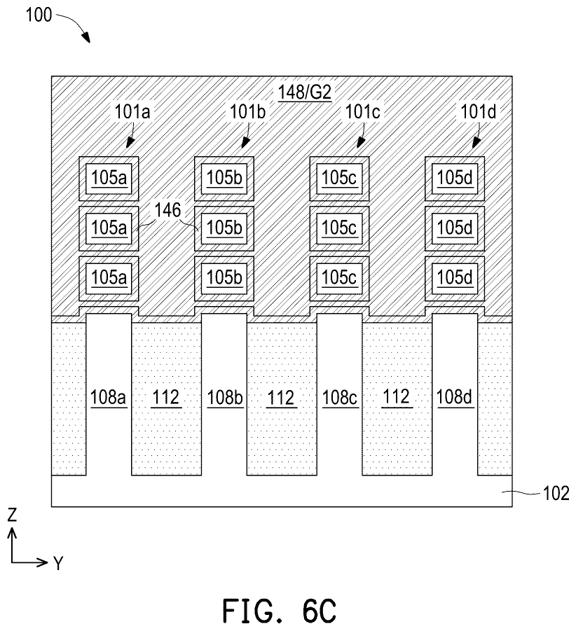

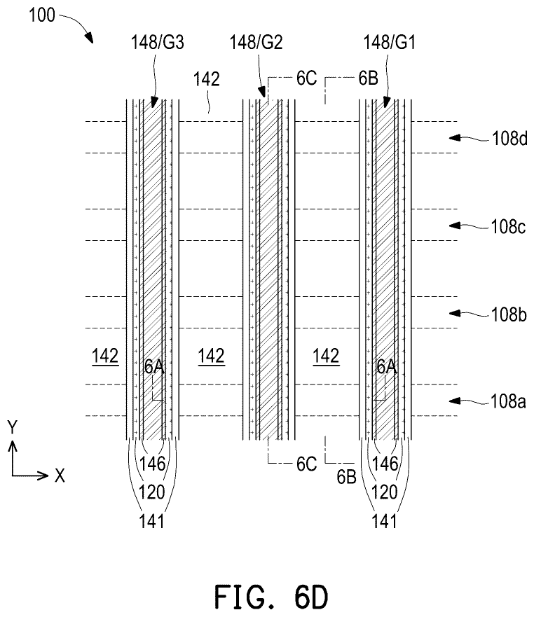

FIGS. 6A-6C are cross-sectional views of the integrated circuit 100, in accordance with some embodiments. FIG. 6D is a top view of the integrated circuit 100 at the stage of processing shown in FIGS. 6A-6C. The cross-sectional views of FIGS. 6A-6C are taken along cut lines 6A, 6B, and 6C, respectively. The cut line 6A is taken through a portion of the semiconductor fin 108a. The cut line 6B is taken in the Y direction through each of the semiconductor fins 108a-d, and, more particularly, through source/drain regions 136a-d of transistors, as will be set forth in more detail below. The cut line 6C is taken in the Y direction through each of the semiconductor fins 108a-d, and, more particularly, through the gate metal 148 of gate layout G2, as will be set forth in more detail below.

In FIGS. 6A-6D, bottom semiconductor layers 132 have been formed on the substrate 102 and each source/drain trench 124. In some embodiments, the bottom semiconductor layers 132 include an intrinsic semiconductor material. In some embodiments, the semiconductor material of the semiconductor layers 132 is a same material as the semiconductor material of the substrate 102.

In FIGS. 6A-6D, bottom dielectric structures 134 have been formed on the bottom semiconductor layer 132 in each source/drain trench 124. In some embodiments, the bottom semiconductor layers 132 include an intrinsic semiconductor material. The bottom dielectric structures 134 can include SiN, SiCN, SiOCN, SiOC, or other suitable dielectric materials. The bottom dielectric structures 134 can be formed by ALD, CVD, or PVD, followed by selected patterning processes. The bottom dielectric structures 134 can help to prevent leakage currents flowing between source/drain regions 136 and the bottom semiconductor layers 132. In some embodiments, the bottom dielectric structures 134 have a thickness between 2 nm and 8 nm.

In FIGS. 6A-6D, dielectric structures 135 have been formed in recesses in the isolation structures 112, as can be seen most clearly in FIG. 6B. In some embodiments, the recesses are formed by one or more etching processes that selectively etches the material of the isolation structures 112 with respect to the material of the dielectric structures 121. The dielectric structures 135 can include SiN, SiCN, SiOCN, SiOC, or other suitable dielectric materials. The dielectric structures 135 can be formed by ALD, CVD, or PVD. In some embodiments, the recessing of the isolation structures can be performed prior to formation of source/drain regions 136. In some embodiments, the dielectric structures 135 are formed in a same process used to form the bottom dielectric structures 134.

In FIGS. 6A-6D, source/drain regions 136 have been formed in the source/drain trenches 124, in accordance with some embodiments. The source/drain regions 136 are epitaxially grown from the channels 105. The source/drain regions 136 are grown on exposed portions of the fins 108 and contact the channels 105. For each stack 126 of channels 105, there are two source/drain regions 136. Some stacks 126 of channels 105 may share a source/drain region 136 with a stack 126 of channels 105 that is adjacent in the X direction.

Source/drain regions 136a are formed in the semiconductor fin 108a. Channels 105a of each stack extend in the X direction between two adjacent source/drain regions 136a, as can be most readily seen in FIG. 6A. Source/drain regions 136b are formed in the semiconductor fin 108b. Channels 105b of each stack extend in the X direction between two adjacent source/drain regions 136b. Source/drain regions 136c are formed in the semiconductor fin 108c. Channels 105c of each stack extend in the X direction between two adjacent source/drain regions 136c. Source/drain regions 136d are formed in the semiconductor fin 108d. Channels 105d of each stack extend in the X direction between two adjacent source/drain regions 136d.

The source/drain regions 136 may include any acceptable semiconductor material, such as appropriate for N-type or P-type devices. For N-type regions, the source/drain regions 136 include materials exerting a tensile strain in the channel regions, such as silicon, SiC, SiCP, SiP, or the like, in some embodiments. For P-type transistors, the source/drain regions 136 include materials exerting a compressive strain in the channel regions, such as SiGe, SiGeB, Ge, GeSn, or the like, in accordance with some embodiments. The source/drain regions 136 may have surfaces raised from respective surfaces of the fins and may have facets. Neighboring source/drain regions 136 may merge in some embodiments to form a singular source/drain region 136 over two neighboring fins 108.

In some embodiments, an in-situ doping process may be performed during formation of the source/drain regions 136 to implant to the source/drain regions 136 with N-type dopants or P-type dopants, depending on the conductivity type of the transistor or region being formed. The N-type dopants can include phosphorus, arsenic, antimony, or other suitable N-type dopants species. The P-type dopants can include boron, gallium, indium, or other suitable P-type dopants species. The source/drain regions 136 may be implanted with dopants followed by an annealing process. The source/drain regions 136 may have an impurity concentration of between about 10¹⁹ cm⁻³ and about 10²¹ cm⁻³.

As set forth previously, in a particular example given herein, the semiconductor fins 108a and 108b corresponds to the location of P-type transistors. Accordingly, the source/drain regions 136a and 136b are P-type source/drain regions. As set forth previously, in a particular example given herein, the semiconductor fins 108c and 108d corresponds to the location of N-type transistors. Accordingly, the source/drain regions 136c and 136d are N-type source/drain regions. In some embodiments, P-type source/drain regions 136 include one or more of SiGe/Si doped with boron, or SiB. In some embodiments, N-type source/drain regions include one or both of SiP and SiAs.

Although FIGS. 6A and 6B illustrates each source drain region 136 as a single epitaxial layer, in practice, each source drain region 136 includes a plurality of epitaxial layers, in some embodiments. A first epitaxial layer of the source drain region 136 is grown on ends of the channels 105. A second epitaxial layer of the source/drain region 136 is grown on the first epitaxial layer covers the side surfaces of the inner spacers 130. A final epitaxial layer of the source/drain region 136 is grown on the third epitaxial layer and fills the source/drain trenches 124. Each epitaxial layer of the source/drain region 136 can have different materials and doping profiles.

In FIGS. 6A-6D, dielectric liner layer 138, a contact etch-stop layer (CESL) 140, and an interlevel dielectric (ILD) 142 have been formed, in accordance with some embodiments. In some embodiments, the dielectric liner layer 140 is a thin dielectric layer conformally deposited on exposed surfaces of the source/drain regions 136, on exposed surfaces of the dielectric structures 121, on exposed surfaces of the isolation structures 112, on exposed surfaces of the dielectric structures 138, and on exposed surfaces of the gate spacer layers 120. The dielectric liner layer 138 can include SiO, SiN, SiOC, SiOCN, SiON, or other suitable dielectric materials. The dielectric liner layer 138 can be deposited by ALD, CVD, PVD, or other suitable deposition processes.

The CESL 140 can include a thin dielectric layer conformally deposited on the dielectric liner layer 138. The CESL 140 can include SiN, SiC, SiOC, SiOCN, SiON, or other suitable dielectric materials. The CESL 140 can be deposited by CVD, ALD, PVD, or other suitable deposition processes. In a particular example, the dielectric liner layer 138 include silicon oxide and the CESL 140 includes silicon nitride. The dielectric liner layer 138 and the CESL 140 together correspond to a CESL bilayer 141. In some embodiments, CESL bilayer 141 this between 3 nm and 6 nm, though other thicknesses can be utilized without departing from the scope of the present disclosure.

The interlevel dielectric layer 142 covers the CESL 140. The interlevel dielectric layer 142 fills the remaining spaces between adjacent sacrificial gate structures 114. The interlevel dielectric layer 142 may correspond to a lowest interlevel dielectric layer of the integrated circuit 100. In some embodiments, the interlevel dielectric layer 142 may be termed ILD0. Though not shown herein, additional interlevel dielectric layer may be formed over the interlevel dielectric layer 142. A network of conductive vias and metal lines may be formed in the upper interlevel dielectric layers. The interlevel dielectric layer 142 can include SiO, SiON, SiN, SiC, SiOC, SiOCN, SiON, or other suitable dielectric materials. The interlevel dielectric layer 142 can be deposited by CVD, ALD, PVD, or other suitable deposition processes.

In some embodiments, a CMP process is performed after deposition of the interlevel dielectric layer 142. The result of the CMP process is that the top surfaces of the interlevel dielectric layer 142, the CESL 140, the gate spacer layer 120, and the sacrificial gate layer 118 are coplanar. The CMP process may also reduce the height of the sacrificial gate structures 114 and the gate spacer layer 120.

As can be seen in FIG. 6B each of the source/drain layers 136 extends laterally over the isolation region 112. Furthermore, the P-type source/drain regions 136a and 136b have grown together over the adjacent isolation region 112. The source/drain regions N-type source/drain regions 136c and 136d have grown together over the adjacent isolation region 112. The growing together of adjacent source/drain regions across the isolation region 112 may be termed “bridging”. This is generally undesirable, depending on circuit layouts. Such bridging is one factor that limits scaling downward of the space between adjacent semiconductor fins. However, as will be set forth in more detail below, embodiments of the present disclosure provide an efficient and effective method and structure for cutting adjoined source/drain regions 136.

In FIGS. 6A-6D, the sacrificial gate layer 118 has been removed, in accordance with some embodiments. The sacrificial gate layer 118 can be removed by an etching process that selectively etches the material of the sacrificial gate layer 118 with respect to adjacent materials, such as the dielectric layer 116 and the gate spacer layers 124. Removal of the sacrificial gate layer 118 results in gate trenches between the gate spacer layers 124.

In FIGS. 6A-6D, an etching process has been performed to remove the sacrificial semiconductor nanostructures 107, in accordance with some embodiments. The sacrificial semiconductor nanostructures 107 can be removed by a selective etching process using an etchant that is selective to the material of the channels 105, such that the sacrificial semiconductor nanostructures 107 are removed without substantially etching the channels 105. The removal of the sacrificial semiconductor nanostructures 107 is referred to as “releasing” the channels 105. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like. In some embodiments, the etching process results in a rounding of side surfaces of the channels 105. The etching process also results in gaps between the channels 105.

In FIGS. 6A-6D, a gate dielectric has been formed, in accordance with some embodiments. The gate dielectric includes an interfacial gate dielectric layer 144 and a high-K gate dielectric layer 146. The interfacial gate dielectric layer 144 has been deposited on exposed portions of the channels 105, in accordance with some embodiments. The interfacial gate dielectric layer 144 forms directly on the exposed portions of the channels 105. The high-K gate dielectric layer 146 forms on the interfacial gate dielectric layer 144 and on other exposed surfaces, such as the exposed sidewalls of the gate spacer layer 120, and the inner spacers 130.

The interfacial gate dielectric layer 144 is wrapped around the channels 105. The interfacial gate dielectric layer 144 can include a dielectric material such as silicon oxide, silicon nitride, or other suitable dielectric materials. The interfacial gate dielectric layer 144 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 144 can be formed by a thermal oxidation process, a chemical vapor deposition (CVD) process, or an atomic layer deposition (ALD) process. The interfacial gate dielectric layer 144 can have a thickness between 0.5 nm and 2 nm. Other materials, deposition processes, and thicknesses can be utilized for the interfacial gate dielectric layer 144 without departing from the scope of the present disclosure. The interfacial gate dielectric layer 144 is shown in FIG. 6A. Though not shown in FIG. 6C, the interfacial gate dielectric layer 144 is also present on the surfaces of the channels 105 between the channels 105 and the high-K gate dielectric layer 146.

The high-K gate dielectric layer 146 is deposited in a conformal deposition process. The conformal deposition process deposits the high-K gate dielectric layer 146 on the interfacial gate dielectric layer 144, on the substrate 102, and on the gate spacer layer 120. The high-K gate dielectric layer 146 is wrapped around the channels 105. The high-K gate dielectric layer 146 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 146 may be formed by CVD, ALD, or any suitable method. Other thicknesses, deposition processes, and materials can be utilized for the high-K gate dielectric layer 146 without departing from the scope of the present disclosure.

In FIGS. 6A-6D, a gate metal 148 has been deposited, in accordance with some embodiments. The gate metal 148 is deposited in place of the sacrificial gate layer 118 and the sacrificial semiconductor nanostructures 107. Accordingly, the gate metal 148 is positioned in the gate trench above the hard mask layer 124 and the above the hard mask layer 150. The gate metal 148 is also wrapped around the channels 105.

As can be seen in FIG. 6C, the gate metal 148 of the gate layout G2 is shorted together around all of the channels 105. Each stack of channels 105a, 105b, 105c, and 105d represent an individual transistor 101a, 101b, 101c, 101d, respectively. More particularly, each location at which the gate metal 148 crosses a semiconductor fin 108 corresponds to the location of an individual transistor 101. At the stage of processing shown in FIGS. 6A-6D, the gate electrodes of all of the transistors 101a-d of the gate region G2 are shorted together. This is also true for the other gate regions G1 and G3. As will be set forth in more detail below, embodiments of the present disclosure provide an effective and efficient method and structure for cutting the gate metal 148 at selected locations. More particularly, a single processes utilized to cut the gate metals 148 and the source/drain regions 136 and to form dielectric isolation structures and the brakes.

FIG. 6D illustrates that the gate metal 148 of each gate region G1-G3 extends unbroken across the fins 108a-d. The dashed lines in FIG. 6D illustrate the locations of the semiconductor fins 108a-d below the gate regions G1-G3, the gate spacer layers 120, the portions of the high-K gate dielectric layer 146 on the sidewalls of the gate spacer layers 120, the interlevel dielectric layer 142, and the CESL bilayer 141.

In FIGS. 6A-6D, a single gate metal 148 is illustrated as the gate electrode of the transistors 101. However, in practice, the gate metal 148 can include multiple gate metals. For example, the gate metal 148 can include one or more liner layers, one or more work function layers, and a gate fill material that fills the remaining spaces between the gate spacer layers 120. The gate metal 148 can include one or more of Ti, TiN, Ta, TaN, Al, Cu, Co, Ru, W, Au, or other suitable conductive materials. The gate metal 148 can be deposited by PVD, ALD, or CVD.

After formation of the gate metal 148, a CMP process is performed to reduce the height of the gate metal 148 and to make a planar top surface of the remaining structures.

The critical dimension of the semiconductor fins 108 and the Y direction is between 10 nm and 90 nm, in accordance with some embodiments. Other dimensions can be utilized without departing from the scope of the present disclosure.

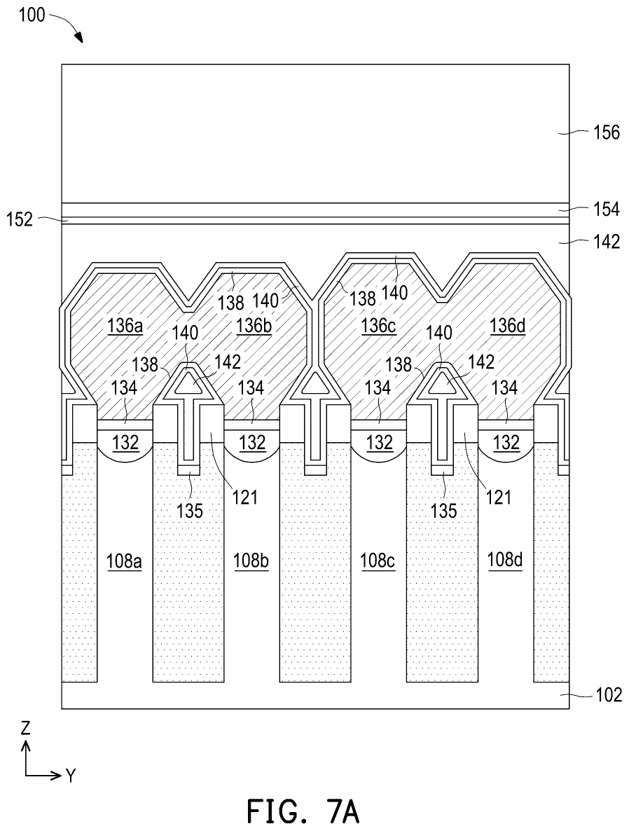

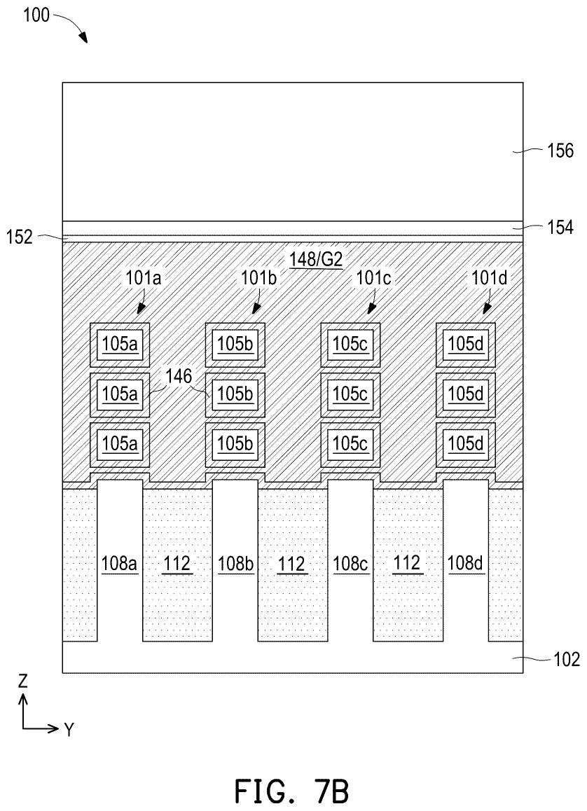

FIGS. 7A and 7B are cross-sectional views of the integrated circuit 100, in accordance with one embodiment. The cross-sectional view of FIG. 7A corresponds to the location of the cross-sectional view of FIG. 6B, though at a subsequent stage of processing. The cross-sectional view of FIG. 7B corresponds to the location of the cross-sectional view of FIG. 6C, at the subsequent stage of processing.

In FIGS. 7A and 7B, a dielectric layer 152 has been formed on the top surface of the integrated circuit 100. In particular, the dielectric layer 152 is on the top surface of the gate metal 148, the interlevel dielectric layer 142, and the top surfaces of other exposed structures. In some embodiments, the dielectric layer 152 includes SiN, SiON, SiOCN, SiOC, or other suitable materials. The dielectric layer 152 helps to prevent oxidation of underlying structures, in accordance with some embodiments.

In FIGS. 7A and 7B, a layer 154 has been formed on the dielectric layer 152. In some embodiments, the layer 154 has a material selected to act as a stop layer for subsequent CMP processes. In some embodiments, the layer 154 includes amorphous silicon. Other materials can be utilized without departing from the scope of the present disclosure. The layer 154 can be deposited by ALD, CVD, PVD, or other suitable deposition processes.

In FIGS. 7A and 7B, a hard mask layer 156 has been formed on the dielectric layer 154. In some embodiments, the hard mask layer 156 has a material selected to act as a stop layer for subsequent CMP processes. In some embodiments, the hard mask layer 156 includes SiN, SiON, SiOCN, SiOC, or other suitable materials. Other materials can be utilized without departing from the scope of the present disclosure. The hard mask layer 156 can be deposited by ALD, CVD, PVD, or other suitable deposition processes.

In some embodiments, the hard mask layer 156 may be termed a reverse cut gate metal layer. In particular, trenches that will be formed in the hard mask layer 156 correspond to locations at which gate metal 148 will not be cut, as will be set forth in more detail below.

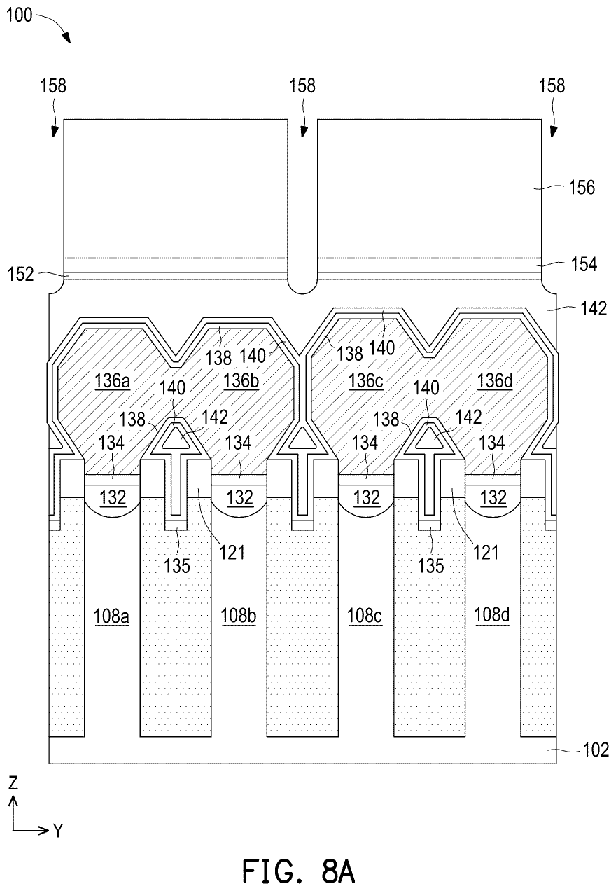

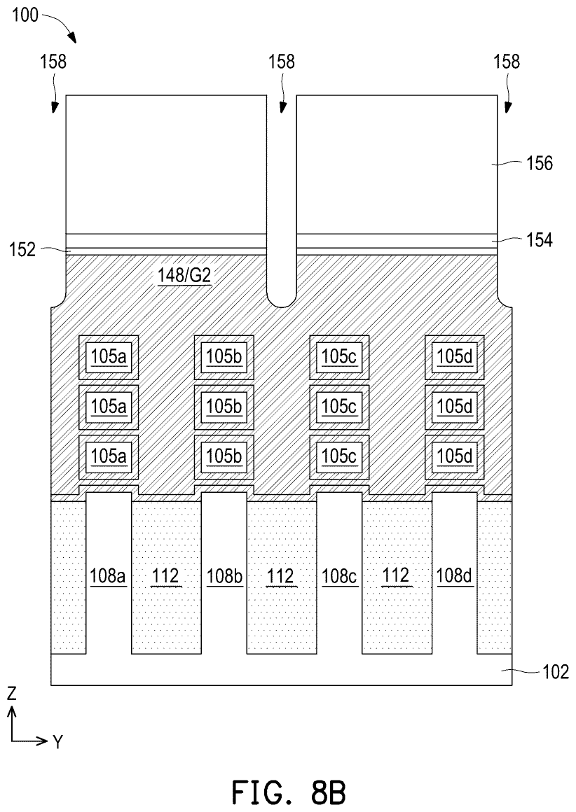

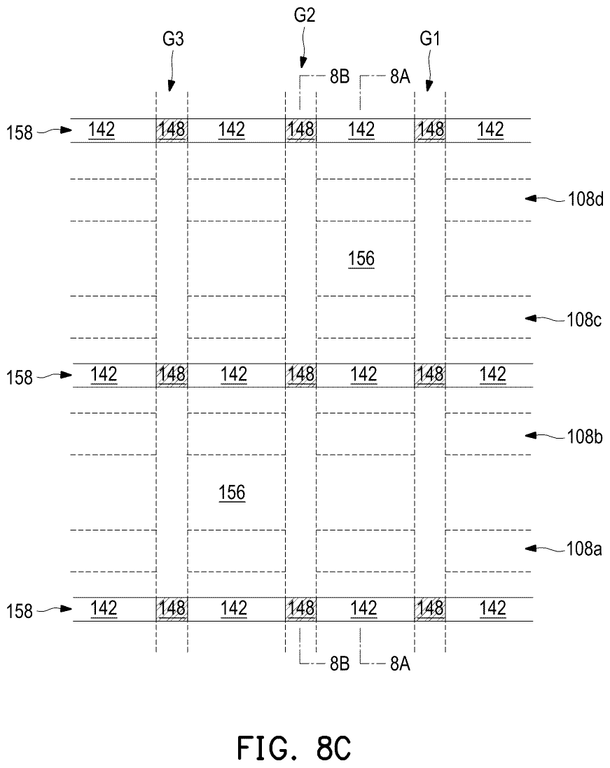

FIGS. 8A and 8B are cross-sectional views of the integrated circuit 100, in accordance with one embodiment. FIG. 8C is a top view of the integrated circuit 100, in accordance with some embodiments. The cross-sectional views of FIGS. 8A and 8B are taken along cut lines 8A and 8B from FIG. 8C.

In FIGS. 8A-8C, an etching process has been performed in conjunction with a photolithography process in order to form a plurality of trenches 158, in accordance with some embodiments. The trenches 158 extend downward through the hard mask layer 156, the layer 154, and the dielectric layer 152. The trenches 158 extend partially into the dielectric layer 142 and the gate metal 148. In particular, the bottom of the trenches 158 correspond to an indent in the top surface of the gate metal 148 (see FIG. 8B) and the interlevel dielectric layer 142 (see FIG. 8A). The trenches 158 extend in the X direction above the isolation structures 112 between the semiconductor fins 108b and 108c (see FIG. 8C). The location of the trenches 158 correspond to locations at which the gate metal 148 will not be cut.

The top view of FIG. 8C illustrates that the gate metal 148 is exposed at some locations in the trenches 158 and the interlevel dielectric layer 142 is exposed at other locations. The locations of the gate regions G1-G3 and the semiconductor fins 108a-108d are shown in dashed lines in FIG. 8C.

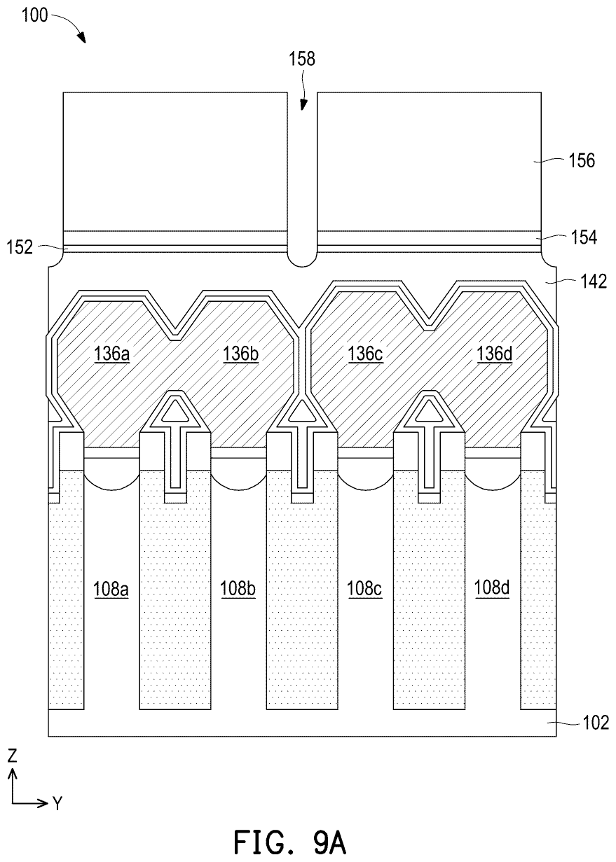

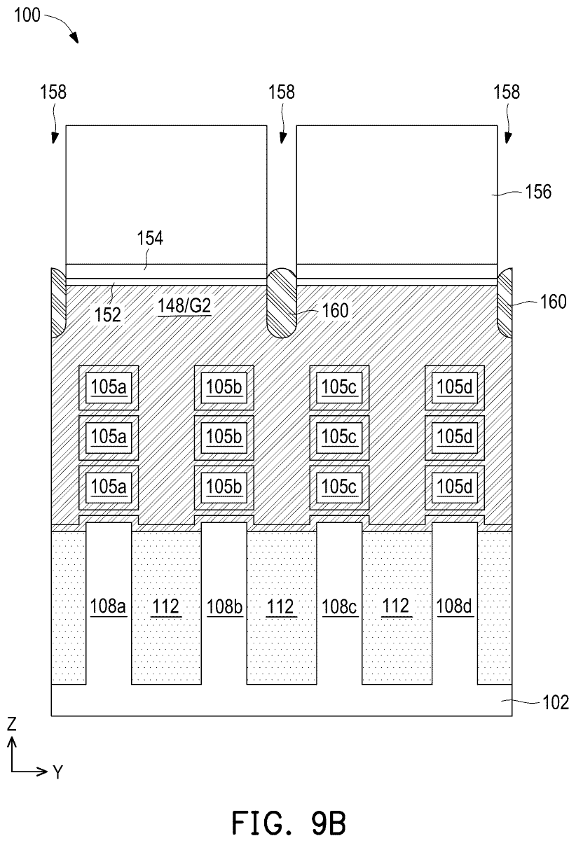

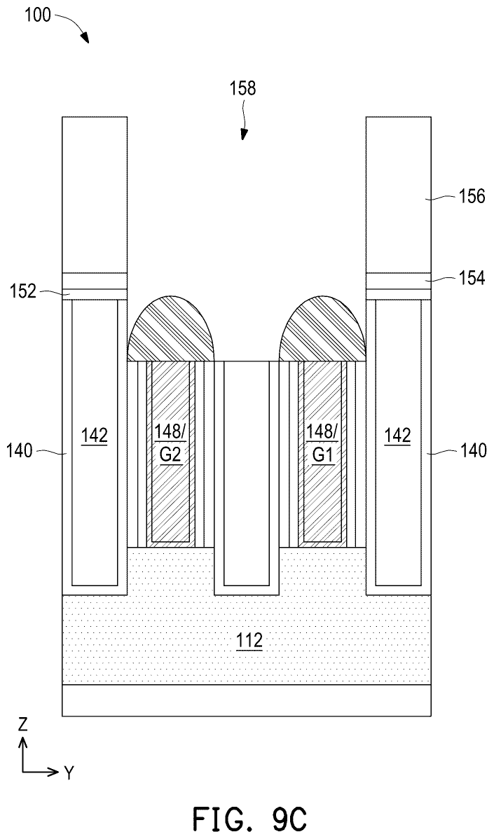

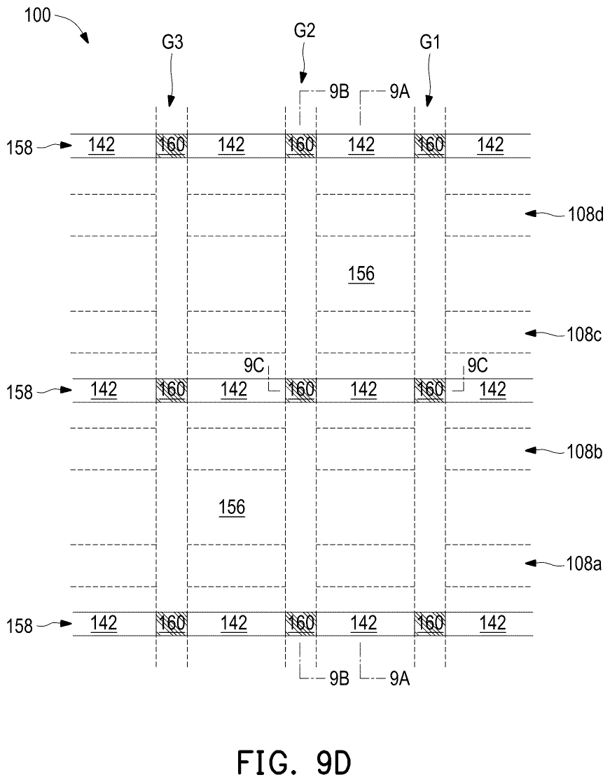

FIGS. 9A, 9B, and 9C are cross-sectional views of the integrated circuit 100, in accordance with one embodiment. FIG. 9D is a top view of the integrated circuit 100, in accordance with some embodiments. The cross-sectional views of FIGS. 8A and 8B are taken along cut lines 9A and 9B from FIG. 9D.

In FIGS. 9A-9D, cap feature structures 160 have been formed in the indents in the gate metal 148 at the bottom of the trenches 158, in accordance with some embodiments. The cap features are formed by performing a deposition process that selectively grows the cap feature structures 160 on the gate metal 148 but not on the exposed dielectric structures. As can be seen in FIG. 9A, the cap feature structures 160 are not present on the indentation in the interlevel dielectric layer 142. FIG. 9B illustrates that the cap feature structures 160 fill the indentation in the gate metal 148 and accumulate higher than the dielectric layer 152 and intermediate between the top and bottom surfaces of the layer 154. Other heights of the cap feature structures 160 can be utilized without departing from the scope of the present disclosure. FIG. 9C illustrates a trench 158 extending between two gate regions G1 and G2. While FIG. 9C illustrates that the trench 158 extends in the X direction only between gate regions G1 and G2, in practice, the trench 158 in the X direction as the gate region G3 as illustrated in FIG. 9D.

In some embodiments, the cap feature structures 160 are formed in a CVD, ALD, or PVD process. In some embodiments, the mechanism selective growth is defined a selected on the surface of the gate metal 140 after exchanging electrons with the material surface and then selectively grown. Accordingly, this works with conductive materials (e.g., the gate metal 148) but not with dielectric materials. In one example, in accordance with some embodiments, the capital structures include ruthenium. In one example, the gate metal 148 includes tungsten. Ruthenium is selected, in some embodiments, because the gate metal 148 can be selectively etched with respect to the ruthenium. Accordingly, locations at which the gate metal 148 is covered by ruthenium, the gate metal 148 will not be etched during the subsequent cut metal gate process. Other materials can be utilized for the cap feature structures 160 and the gate metals 148 without departing from the scope of the present disclosure. In some embodiments, the thickness of the cap feature structures 160 between 2 nm and 20 nm, though other dimensions can be utilized without departing from the scope of the present disclosure. In some embodiments, the cap feature structures 160 have a width in the Y direction between 10 nm and 30 nm. In some embodiments, the cap feature structures are cap metals or cap metal structures.

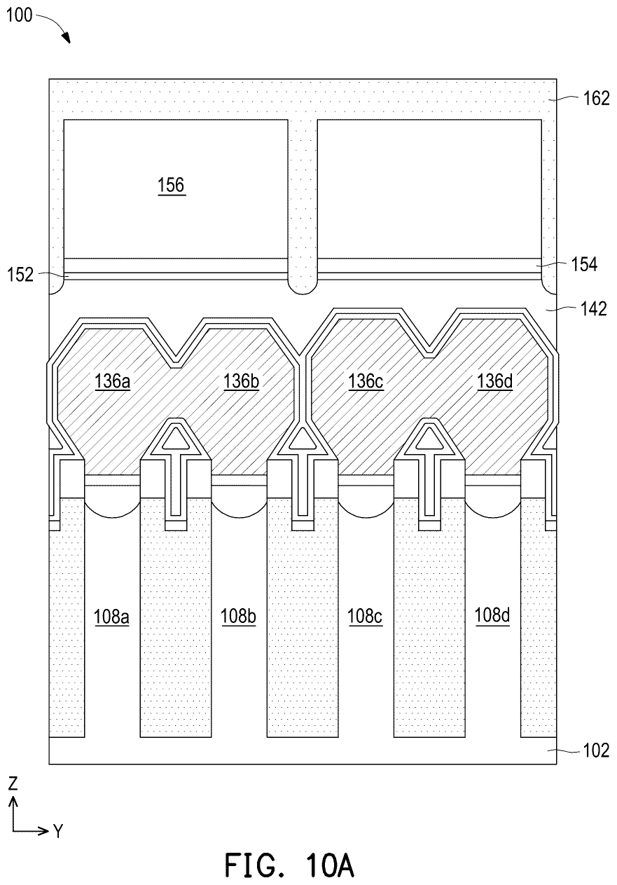

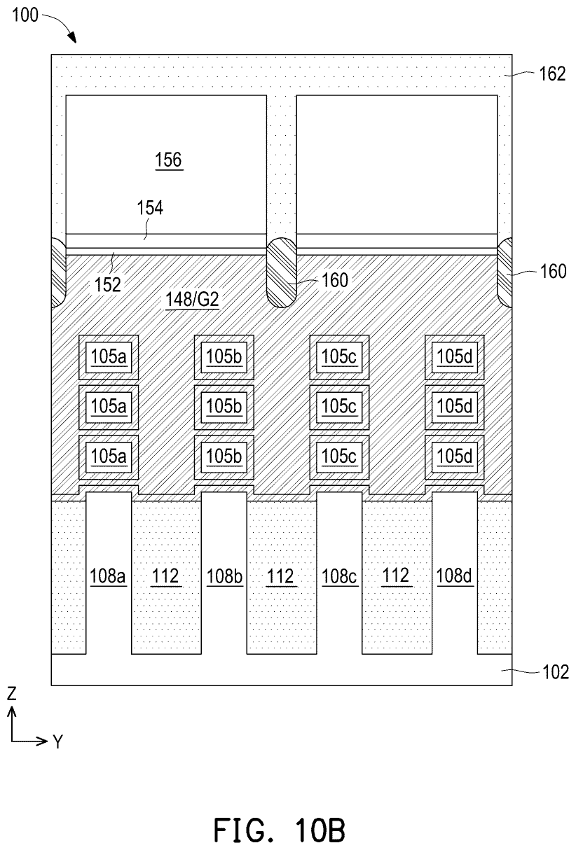

FIGS. 10A and 10B are cross-sectional views of the integrated circuit 100, in accordance with one embodiment. In FIGS. 10A and 10B, a dielectric layer 162 has been deposited on the hard mask layer 156 and in the trenches 158. The dielectric layer 162 can be deposited by CVD, ALD, PVD, or other suitable deposition processes. The dielectric layer 162 can include SiN, SiON, SiOCN, SiOC, or other suitable dielectric materials.

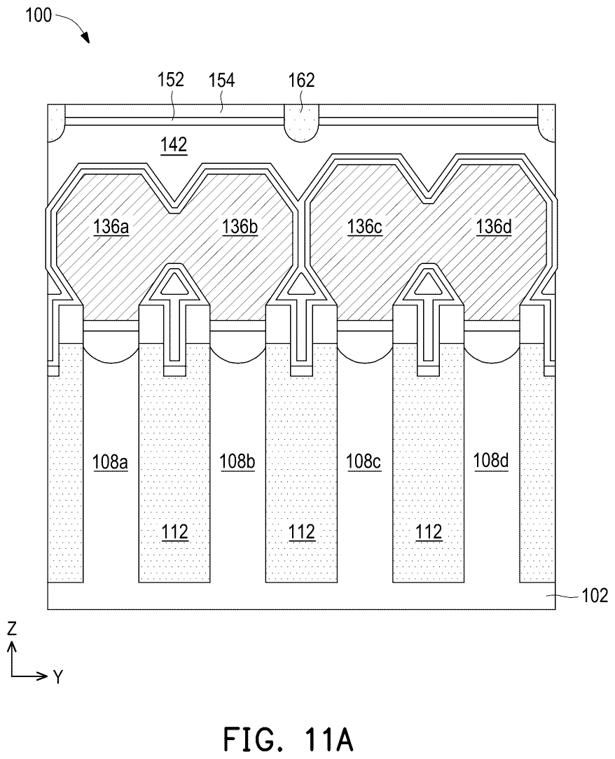

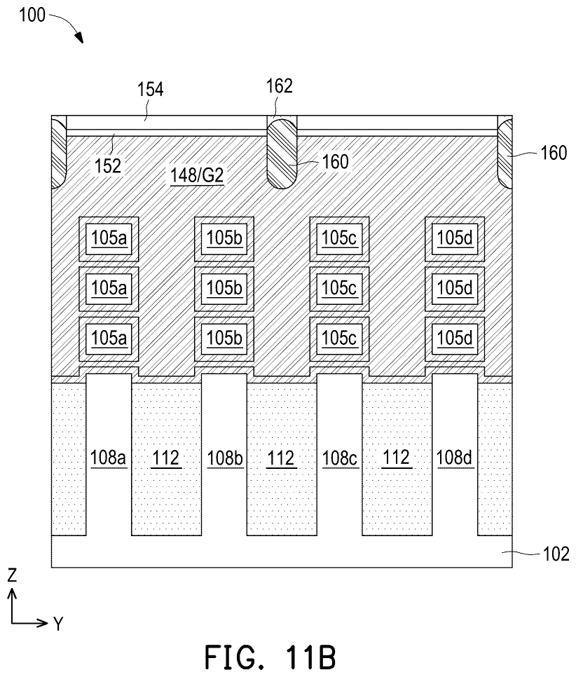

FIGS. 11A and 11B are cross-sectional views of the integrated circuit 100, in accordance with one embodiment. In FIGS. 11A and 11B, a CMP process has been performed. The CMP process removes the dielectric layer 162 and the hard mask layer 156 at locations higher than the top surface of the layer 154. As set forth previously, the layer 154 is a stop layer for the CMP process. Accordingly, the remaining portions of the dielectric layer 162 in the indents in the interlevel dielectric layer 142 (see FIG. 11A) and on the cap feature structures 160 (see FIG. 11B) have a top surface that is coplanar with the top surface of the layer 154.

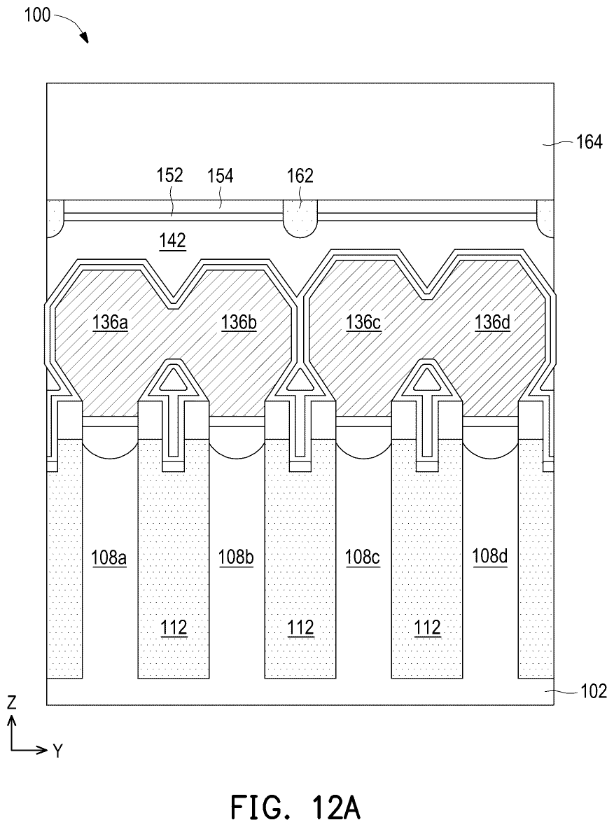

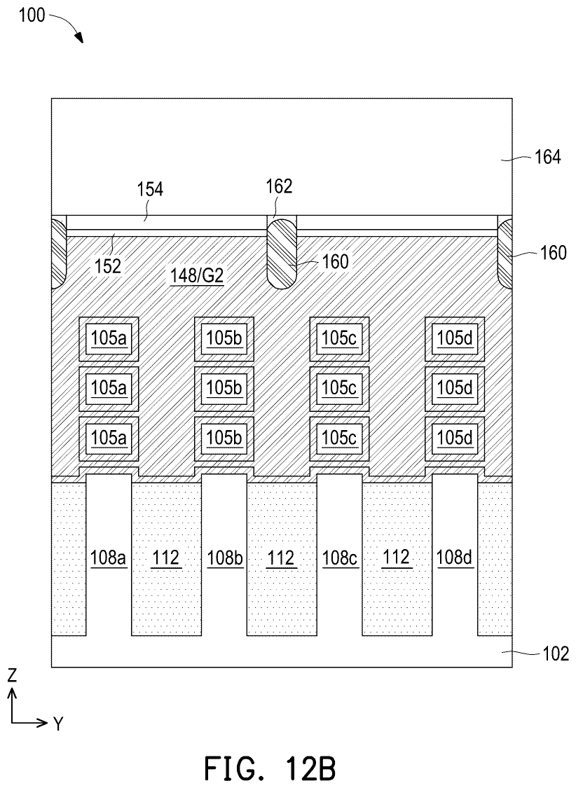

FIGS. 12A and 12B are cross-sectional views of the integrated circuit 100, in accordance with one embodiment. In FIGS. 12A and 12B, a hard mask layer 164 has been deposited on the top surface of the layer 154 and the remaining portions of the dielectric layer 162. The hard mask layer 164 can include SiN, SiON, SiOCN, SiC, or other suitable dielectric materials. The hard mask layer 164 can be deposited by CVD, ALD, PVD, or other suitable deposition processes.

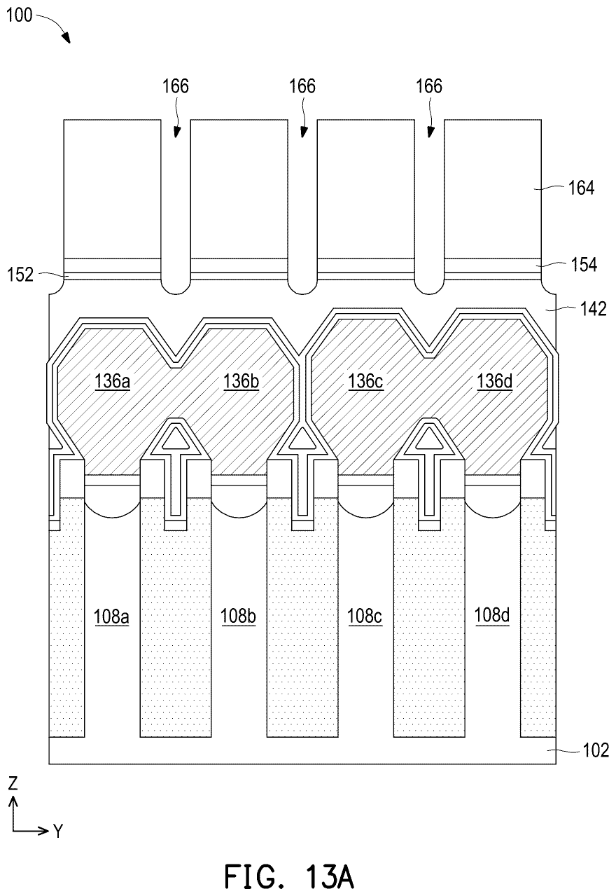

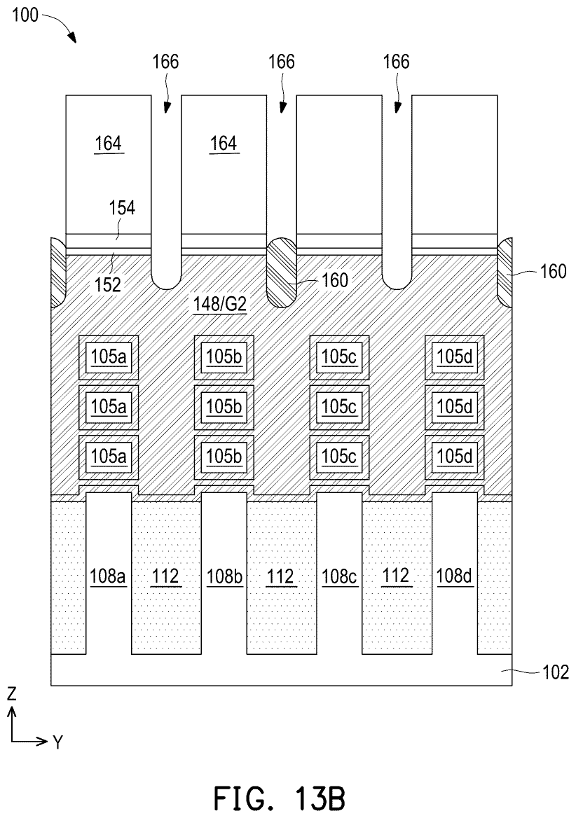

FIGS. 13A and 13B are cross-sectional views of the integrated circuit 100, in accordance with one embodiment. In FIGS. 13A and 13B and etching process has been performed, in conjunction with a photolithography process, to form trenches 166. The trenches 166 extends in the X direction above the isolation structures 112 laterally between adjacent fins. The location of the trenches 166 correspond to locations at which gate metals 148 will be cut (except where prevented by cap feature structures 160) and at which the source/drain regions 136 will be cut. The etching process of partially into the gate metal 148 (see FIG. 13B) and the interlevel dielectric layer 142 (see FIG. 13A). The gate metal 148 is not etched were covered by the cap feature structures 160. The etching process shown in FIGS. 13A and 13B may be termed an initial etching step of an etching process to cut the gate metal 148 and the source/drain regions 136.

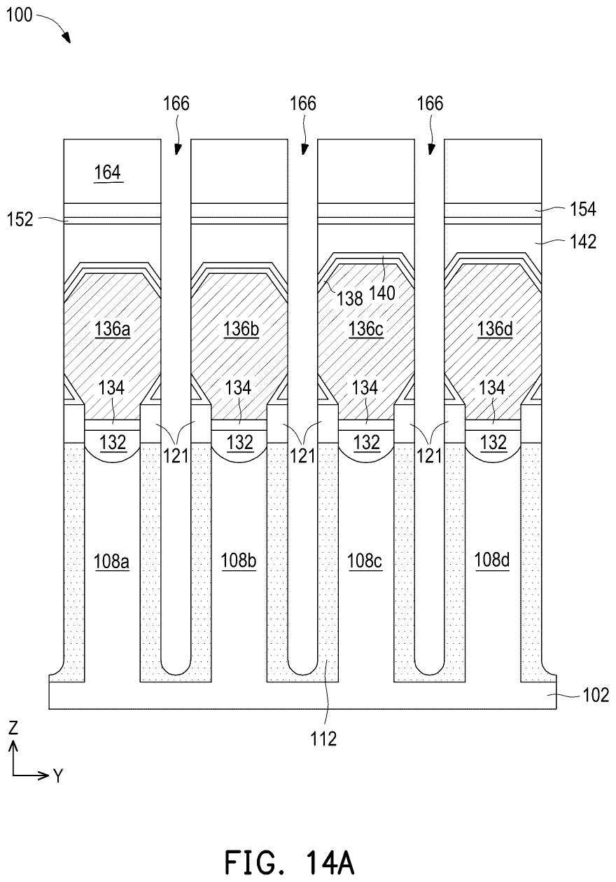

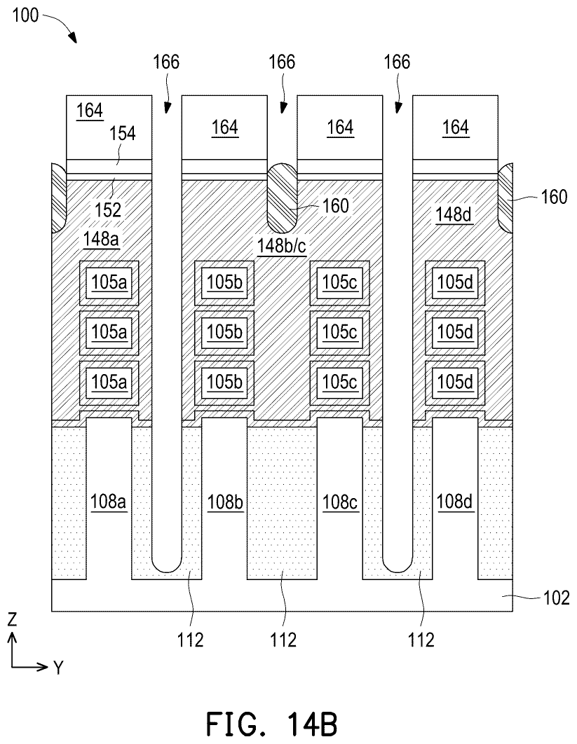

FIGS. 14A and 14B are cross-sectional views of the integrated circuit 100, in accordance with one embodiment. FIG. 14C is a top view of the integrated circuit 100, in accordance with some embodiments. The cross-sectional views of FIGS. 14A and 14B are taken along cut lines 14A and 14B from FIG. 14C.

In FIGS. 14A-14C, a further etching step of the etching process has been performed, in accordance with some embodiments. As can be seen in FIG. 14A, the etching process extends the depth of the trenches 166 through the source/drain regions 136. Most particularly, the source/drain regions 136 are etched at those locations where there joint the thin adjacent source/drain region. In particular, the trench 166 that extends downward between the semiconductor fins 108a and 108b cuts the portions of the source/drain regions 136a and 136b that had grown together, thereby physically and electrically isolating them from each other. The trench 166 that extends downward between the semiconductor fins 108b and 108c cuts the portions of the source/drain regions 136b and 136c that had grown together, thereby physically and electrically isolating them from each other. The trench 166 that extends downward between the semiconductor fins 108c and 108d cuts the portions of the source/drain regions 136c and 136c that had grown together, thereby physically and electrically isolating them from each other.

In some embodiments, the trenches 166 have a tapered profile in which their width decreases with depth (narrower at bottom than at top). In some embodiments, to form the trenches 166, it should etch different material, for example the dielectric layer 142 (oxide, in some embodiments), CESL 140, (nitride base, in some embodiments), source/drain region 136 (silicon, in some embodiments,) thus resulting in a different profile. Accordingly, in some embodiments different sidewall profiles may occur on the dielectric layer 142, the source/drain region 136a, the layer 121, etc . . . due to material differences. For example, if etchant is favorable to etch the dielectric material of the dielectric layer 142 more than the semiconductor material of source/drain region 136, the sidewall of 142 may be etched more, and it will extend deeper in Y direction. In some embodiments, the trenches for cutting the source/drain regions 136 are different depth from the trenches used to cut the gate metal.

As can be seen in FIG. 14B, the etching process extends the depth of the trenches 166 through the gate metal 148 (except where the cap feature structures 160 are present. Most particularly, the gate metal 148 is etched at those locations. In particular, the trench 166 that extends downward between the semiconductor fins 108a and 108b cuts the gate metal 148 into a gate metal portion 148a and a gate metal portion 148bc. The gate metal portion 148a is wrapped around the channels 148a of the transistor 101a. The gate metal portion 148a corresponds to a gate electrode of the transistor 101a. The gate metal portion 148bc is wrapped around the channels 105b of the transistor 101b and the channels 105c of the transistor 101c. metal portion 148bc corresponds to a joint gate electrode of the transistors 105b and 105c. Said another way, the gate electrodes of the transistors 105b and 105c are shorted together. The gate metal portions 148a and 148bc are electrically and physically isolated from each other. The cap feature structures 160 are positioned at locations at which it is desired that the gate electrodes of adjacent transistors are to be electrically shorted with each other, in accordance with a circuit layout.

The trench 166 that extends downward between the semiconductor fins 108c and 108d cuts a gate metal portion 148d from the gate metal portion 148bc. The gate metal portions 148bc and 148d are electrically and physically isolated from each other.

The formation of the trenches 166 includes etching through portions of the hard mask layer 164, the layer 154, the dielectric layer 152, the interlevel dielectric layer 142, the CESL layer 140, the dielectric layer 138, the dielectric structures 121, and the isolation structures 112.

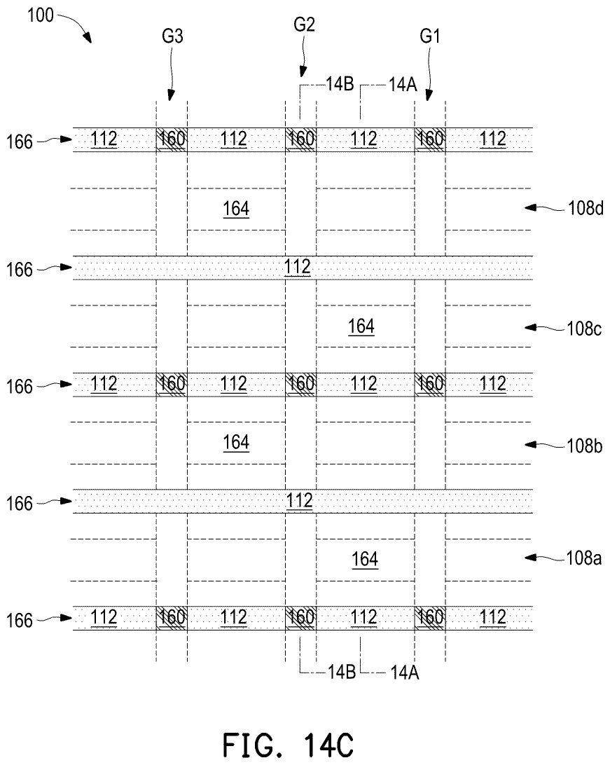

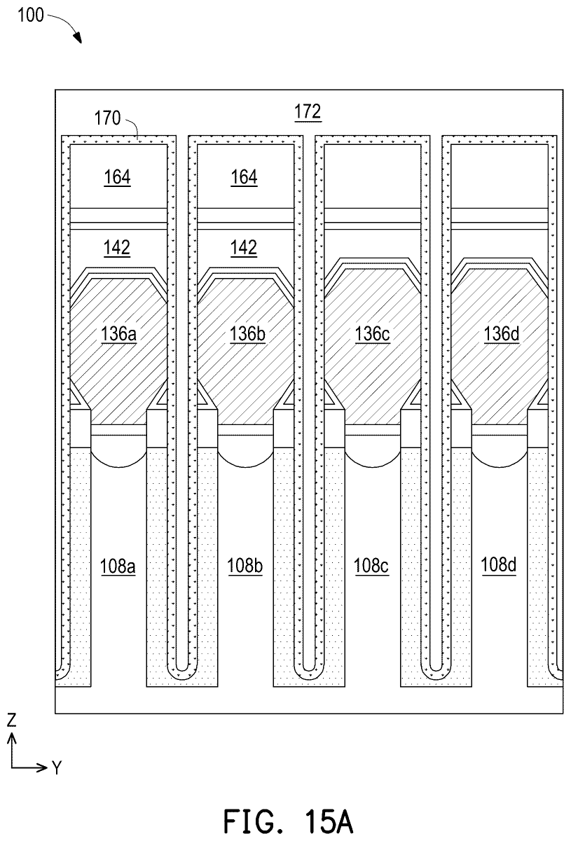

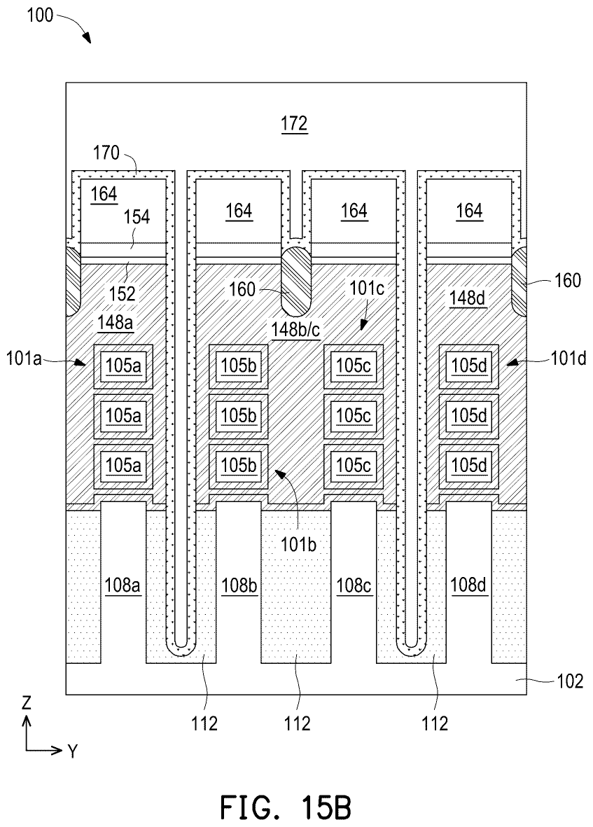

FIGS. 15A and 15B are cross-sectional views of the integrated circuit 100, in accordance with one embodiment. In FIGS. 15A and 15B, a dielectric liner layer 170 has been deposited conformally on all exposed surfaces. Most particularly, the dielectric liner layer 170 lines the sidewalls of the trenches 166. The dielectric liner layer 170 includes one SiN, SiON, SiOCN, SiCN, or other suitable dielectric materials. The dielectric liner layer 170 can be deposited by ALD, CVD, PVD, or other suitable deposition processes.

In FIGS. 15A and 15B, a dielectric layer 172 has been deposited on the dielectric liner layer 170, in accordance with some embodiments. Most particularly, the dielectric layer fills the remaining portions of the trenches 166. The dielectric layer 170 includes one SiN, SiON, SiOCN, SiCN, or other suitable dielectric materials. The dielectric layer 170 can be deposited by ALD, CVD, PVD, or other suitable deposition processes. In one example, the dielectric liner layer 170 includes SiN and the dielectric layer 172 includes SiO. In some embodiments, the dielectric layer 170 includes the ethyl orthosilicate. In some embodiments, a single dielectric layer is utilized rather than a dielectric layer 172 and the dielectric layer 170.

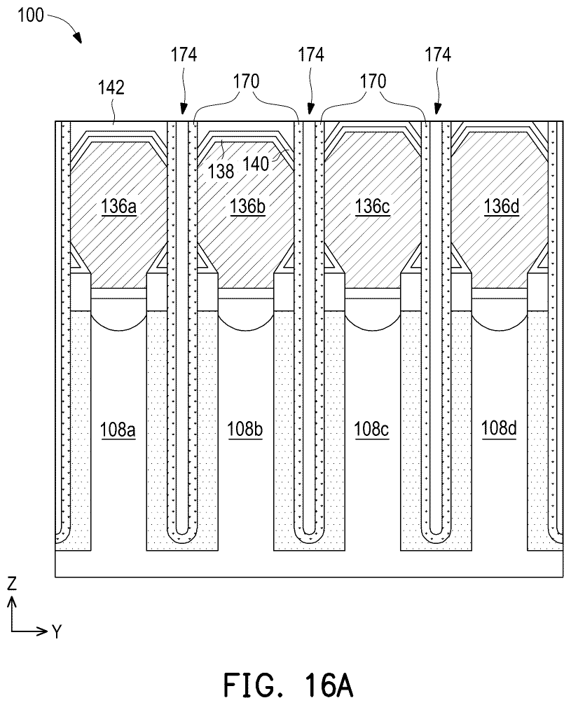

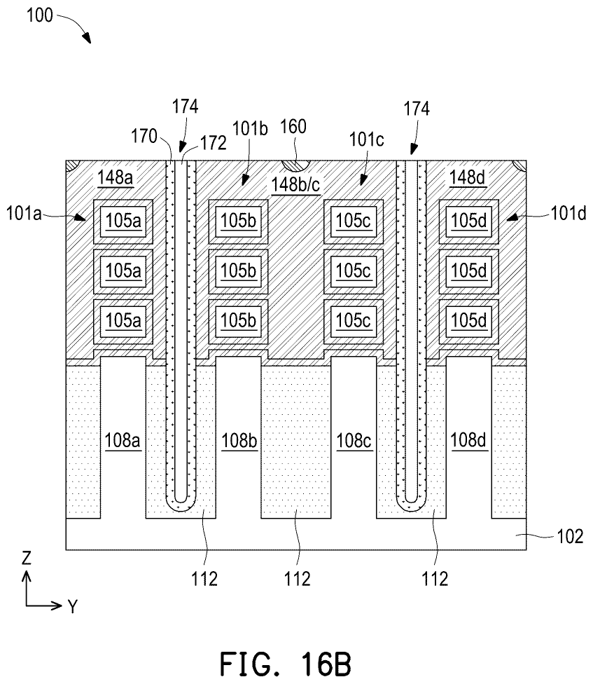

FIGS. 16A and 16B are cross-sectional views of the integrated circuit 100, in accordance with one embodiment. FIG. 16C is a top view of the integrated circuit 100, in accordance with some embodiments. The cross-sectional views of FIGS. 16A and 16B are taken along cut lines 16A and 16B from FIG. 16C.

In FIGS. 16A-16C, dielectric isolation structures 174 have been formed in the trenches 166, in accordance with some embodiments. More particularly, a CMP process has been performed to remove excess layers above the top surface of the interlevel dielectric layer 142. The result is that the hard mask layer 164, the layer 154, and the dielectric layer 152 have been removed. The layer 154 can be removed by using methods or chemicals in the CMP process that etches the layer 154 such that it does not act as a stop layer for this particular CMP process. Furthermore, excess material from the dielectric liner layer 170 and the dielectric layer 172 have been removed.

The CMP process leaves the dielectric isolation structures 174, made up of the dielectric liner layer 170 and the dielectric layer 172, in the trenches 166. The dielectric isolation 174 structures electrically isolate and physically separate the adjacent source/drain regions 136 from each other. The dielectric isolation structures 174 electrically isolate and physically separate adjacent portions of the gate metal 148. In some embodiments, the dielectric isolation structures 174 have a width in the Y direction between 10 nm and 33 nm between portions of the gate metal 148. In some embodiments, the dielectric isolation structures 174 have a depth between 110 nm and 160 nm. Other dimensions can be utilized without departing from the scope of the present disclosure.

As set forth above, the gate metal 148 and the source/drain regions 136 are cut in a same process. The collectively ground cap feature 160 is utilized to prevent putting the gate metal 148 at selected locations. The dielectric isolation structures 174 are formed between the source/drain regions 136 and the adjacent portions of the gate metal 148 in a same process.

In some embodiments, the lateral surfaces of the source/drain regions 136 over the isolation structures 112 are vertical. In some embodiments, become the dielectric isolation structures 174 is between 10 nm and 30 nm, though other widths can be utilized without departing from the scope of the present disclosure. In some embodiments, the depth of the dielectric isolation structures 174 relative to the top of the gate metal 148 is between 80 nm and 180 nm, though other dimensions can be utilized without departing from the scope of the present disclosure.

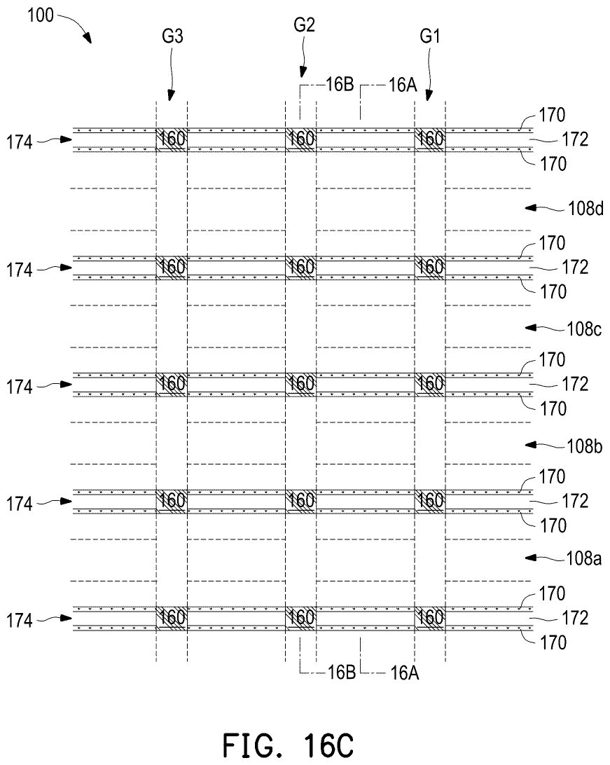

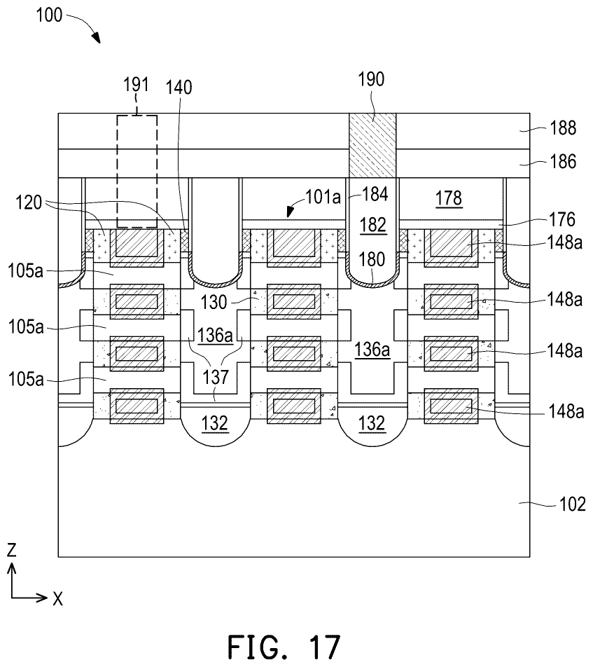

FIG. 17 is a cross-sectional view of the integrated circuit 100, in accordance with some embodiments.

In FIG. 17, a dielectric layer 176 has been deposited on the gate metal 148, the gate spacer layers 120, and on other exposed surfaces. The dielectric layer 176 can include SiN, SiCN, SiON, SiOCN, SiOC, or other suitable dielectric materials. The dielectric layer 176 can be deposited by CVD, ALD, PVD, or other suitable deposition processes.

In FIG. 17, an interlevel dielectric layer 178 has been deposited, in accordance with some embodiments. The interlevel dielectric layer 178 can include SiO, SiN, SiON, SiOC, SiOCN, or other suitable deposition processes. The interlevel dielectric layer 178 can be deposited by CVD, ALD, PVD, or other suitable deposition processes.

FIG. 17 illustrates that the source/drain regions 136 include a first epitaxial layer 137. As described previously, the source/drain regions 136 can include a first epitaxial layer grown from ends of the channels 105, a second epitaxial layer grown on the first epitaxial layer, and a main epitaxial fill layer.

In FIG. 17, the source/drain regions 136 have been recessed and a silicide layer 180 has been formed in preparation for forming source/drain contacts 182. Formation of the silicide layer 180 can include depositing a thin metal layer Ti, Ni, Al, Ta, or other suitable and performing a thermal annealing process that results in formation of the silicide layer 180 from the metal layer. Accordingly, the silicide layer 180 can include titanium silicide, nickel silicide, aluminum silicide, tantalum silicide, or other suitable silicides.

After formation of the silicide layer 180, source/drain contacts 182 are formed on the silicide layer 180. The source/drain contacts 182 include a metal such as W, Ta, Ti, Al, Ru, Co, Au, or other suitable materials. The source/drain contacts 182 can be formed by PVD, ALD, CVD, or other suitable deposition processes. In some embodiments, the source/drain contacts 182 include one or more liner layers of TiN, TaN, or other materials, followed by deposition of the metal filling material of the source/drain contacts 182. In FIG. 17, a liner layer 184 is formed before the formation of the source/drain contacts 182. The liner layer can include a dielectric material or a conductive material.

In FIG. 17, a dielectric layer 186 has been formed on the source/drain contacts 182 and on the interlevel dielectric layer 178. The dielectric layer 186 can include SiN, SiCN, SiON, SiOCN, SiOC, or other suitable dielectric materials. The dielectric layer 186 can be deposited by CVD, ALD, PVD, or other suitable deposition processes.

In FIG. 17, on the interlevel dielectric layer 188 has been formed on the dielectric layer 186. The interlevel dielectric layer 188 can include SiO, SiN, SiCN, SiON, SiOCN, SiOC, or other suitable dielectric materials. The dielectric layer 186 can be deposited by CVD, ALD, PVD, or other suitable deposition processes.

FIG. 17, conductive vias 190 have been formed contacts of selected source/drain contacts 182. Conductive vias can be formed by first forming apertures in the dielectric layers 188 and 186 to expose selected source/drain contacts. The apertures can be filled by depositing a conductive material. The conductive material can include W, Ti, Al, Au, Co, Cu, TiN, TaN, or other suitable conductive materials. The conductive material can be deposited by PVD, ALD, CVD, or other suitable deposition processes. The dashed box 191 illustrates the profile a gate contact configured to contact the gate metal 148 at a selected location, either in the cut of 17, or offset in the Y direction.

FIG. 18 is a cross-sectional view of the integrated circuit 100, in accordance with some embodiments. The view of FIG. 18 is vertically flipped with respect to the view of FIGS. 1-17. In FIG. 18, after formation of metal lines and conductive vias above the transistors 10 one, the integrated circuit is flipped to form metal lines and conductive vias the backside of the integrated circuit 100.

In some embodiments, this includes a CMP or grinding process to remove portions of the semiconductor substrate 102 to expose the isolation structures 112, depositing backside substrate materials such as one or more dielectric layers, and forming trenches to expose the source/drain regions 136. A silicide 192 is formed on the backside of the source/drain trenches 136. The silicide 192 can be substantially similar to the silicide 180. In some embodiments, the silicide 192 includes TiSi, MoSi, RuSi, a Zr Eiffel material, or other suitable materials. Silicide 192 can have a thickness between 1 nm and 5 nm, though other dimensions can be utilized without departing from the scope of the present disclosure.

Backside source/drain contacts 194 are then formed electrically connected to the source/drain regions 136. In some embodiments, the backside source/drain contacts 194 include W, Ru, Mo, or other suitable materials. In some embodiments, the backside source/drain contacts 194 have a critical dimension between 8 nm and 16 nm, though other materials can be utilized without departing from the scope of the present disclosure.

A dielectric liner layer 196 may be deposited in the backside trenches. The dielectric liner layer 196 can include SiN, SiCN, SiOCN, SiOC, or other suitable dielectric materials. The dielectric liner layer 196 can have a thickness between one nanometer and 5 nm, though other thicknesses can be utilized without departing from the scope of the present disclosure.

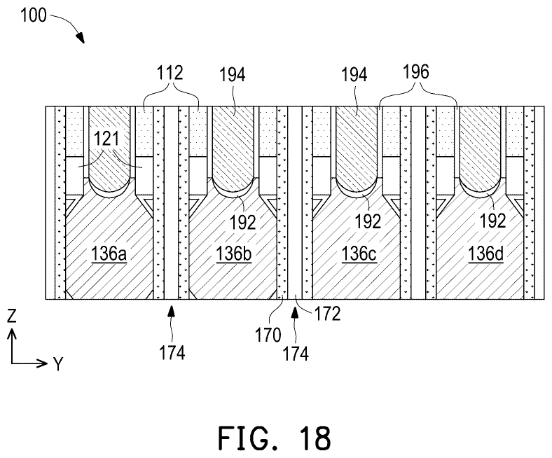

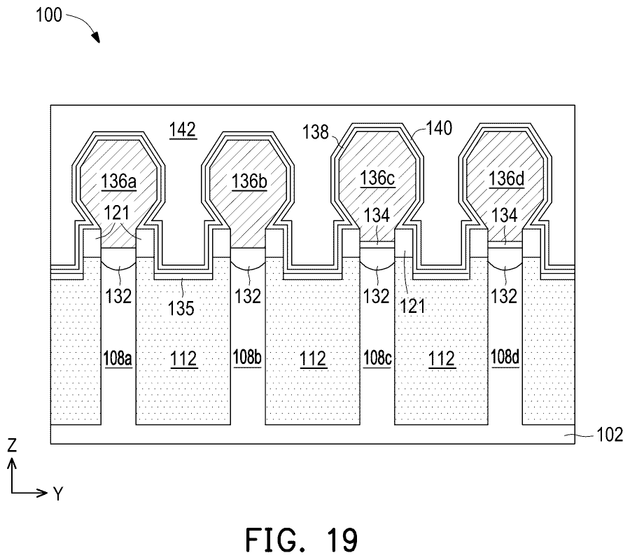

FIGS. 19-21 cross-sectional views of an integrated circuit 100 at various stages of processing, in accordance with some embodiments.

FIG. 19 is a cross-sectional view of the integrated circuit 100 at a stage of processing substantially similar to that shown in relation to FIGS. 6A-6D, in accordance with some embodiments. In other words, source/drain regions 136 and gate metal 148 have been formed. FIG. 19 difference from FIGS. 1-18 in that the semiconductor fins 108 are spaced apart by larger distances such that the source/drain regions 136 do not join each other over the isolation structures 112.

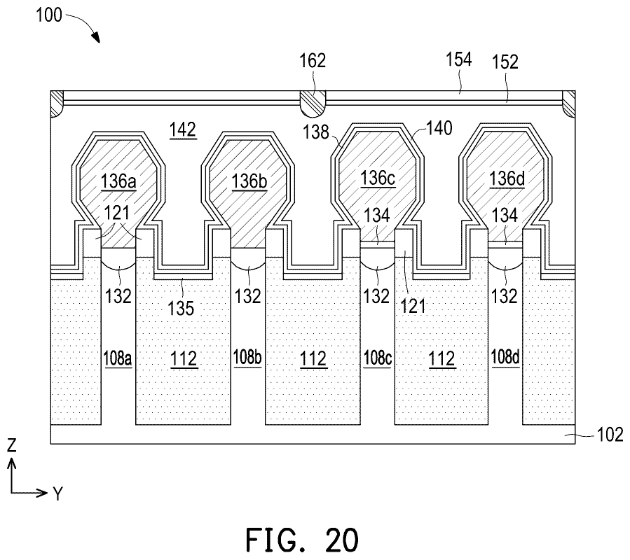

FIG. 20 is a cross-sectional view of the integrated circuit 100 at a stage of processing substantially similar to the stage of processing shown in relation to FIGS. 11A and 11B, in accordance with some embodiments. The remnants of the dielectric layer 162 are shown in the indentations in the interlevel dielectric layer 142. Though not shown in FIG. 20, the cap feature structures 160 have been formed at the selected locations.

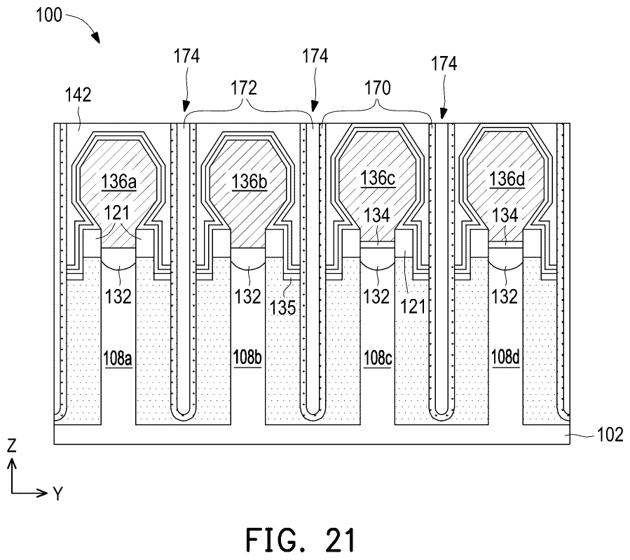

FIG. 21 is a cross-sectional view of the integrated circuit 100 at a stage of processing substantially similar to the stage of processing shown in relation to FIGS. 16A-16C, in accordance with some embodiments. In particular, the dielectric isolation structures 174 have been formed between adjacent portions of the gate metal 148 and between adjacent source/drain regions 136.

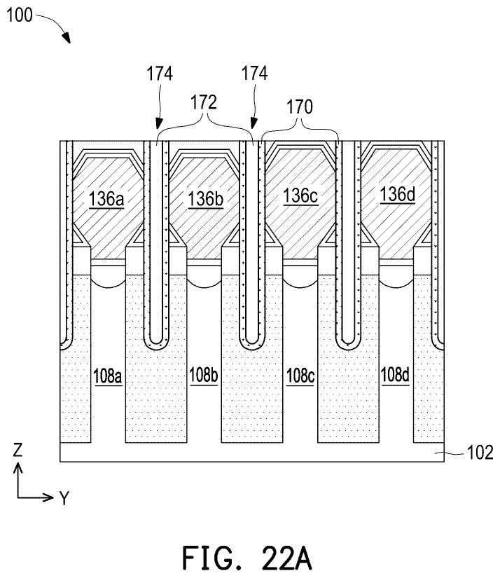

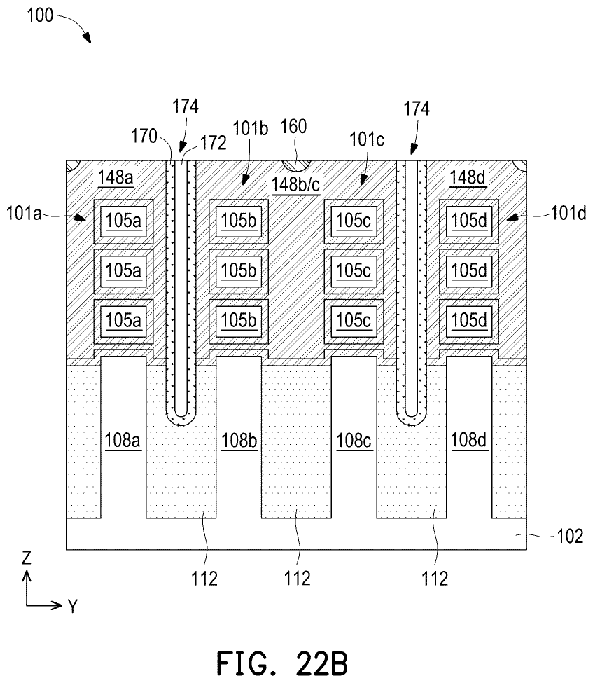

FIGS. 22A and 22B are cross-sectional views of an integrated circuit 100 at a stage of processing substantially similar to that shown in FIGS. 16A-16D, in accordance with some embodiments. The dielectric isolation structures 174 have been formed. The structure of FIG. 22 is different in that the dielectric isolation structures 174 are shallower and do not extend near the bottom of the isolation structures 112.

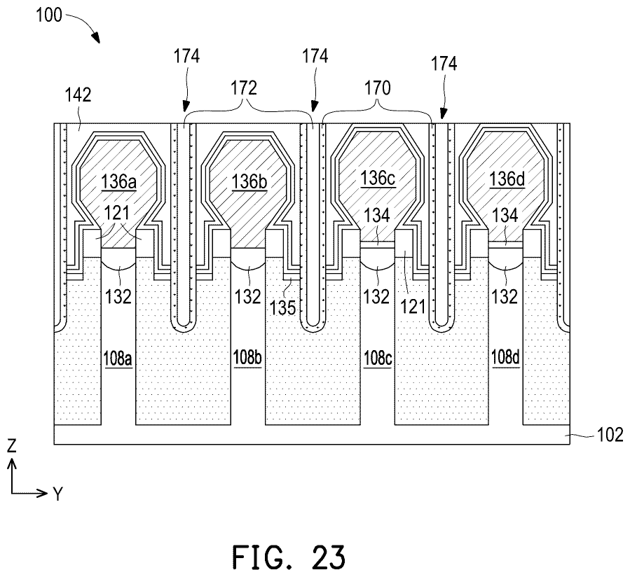

FIG. 23 is a cross-sectional view of an integrated circuit 100 at a stage of processing substantially similar to that shown in FIGS. 16A-16D, in accordance with some embodiments. The dielectric isolation structures 174 have been formed. The structure of FIG. 23 is different in that the adjacent source/drain regions 136 are spaced further apart such that no bridging has occurred and the dielectric isolation structures 174 do not cut the source/drain regions 136. The dielectric isolation structures 174 are shallower and do not extend near the bottom of the trench isolation structures 112.

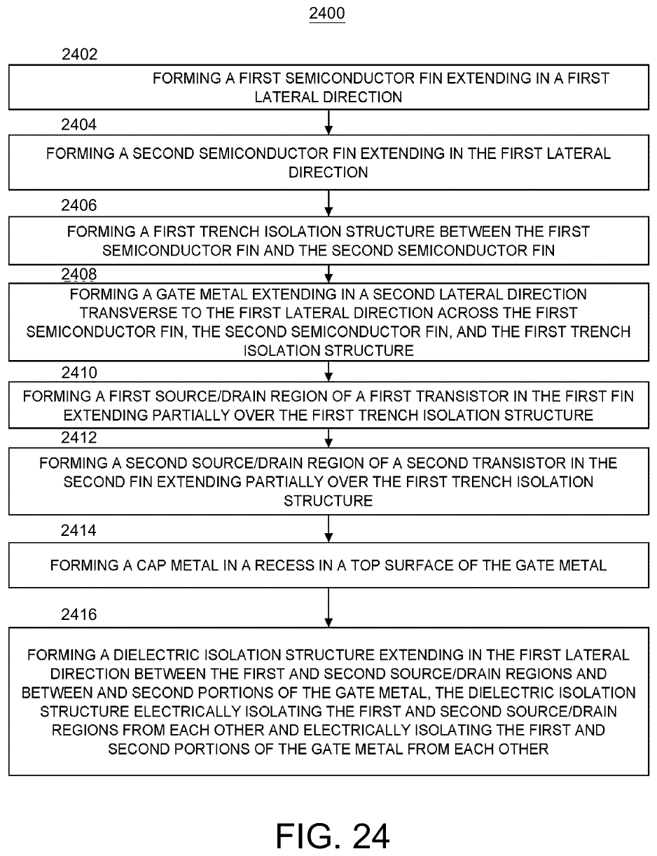

FIG. 24 is a flow diagram of a method 2400 for forming an integrated circuit, in accordance with some embodiments. The method 2400 can utilize the structures, processes, and systems described in relation to FIGS. 1-23.

At 2402, the method 2400 includes forming a first semiconductor fin extending in a first lateral direction. At 2404, the method 2400 includes forming a second semiconductor fin extending in the first lateral direction. At 2406, the method 2400 includes depositing a first isolation structure between the first semiconductor fin and the second semiconductor fin. One example of first and second semiconductor fins are the first and second semiconductor fins 108a and 108b FIG. 2B. One example of a first isolation structure is the isolation structure 112 of FIG. 2B. At 2408, the method 2400 includes depositing a gate metal extending in a second lateral direction transverse to the first lateral direction across the first semiconductor fin, the second semiconductor fin, and the first isolation structure. One example of a gate metal is the gate metal 148 of FIGS. 6A-6D. At 2410, the method 2400 includes growing a first source/drain region of a first transistor in the first fin extending partially over the first isolation structure. At 2412, the method 2400 includes growing a second source/drain region of a second transistor in the second fin extending partially over the first isolation structure. One example of first and second source/drain regions are the first and second source/drain regions 136a and 136b of FIG. 6B. At 2414, the method 2400 includes depositing a cap feature in a recess in a top surface of the gate metal. One example of a cap feature is the cap feature 160 of FIG. 9B. At 2416, the method 2400 includes forming a dielectric isolation structure extending in the first lateral direction between the first and second source/drain regions and between first and second portions of the gate metal, the dielectric isolation structure electrically isolating the first and second source/drain regions from each other and electrically isolating the first and second portions of the first gate metal from each other. One example of a dielectric isolation structure is the dielectric isolation structure 174 of FIGS. 16A-16C.

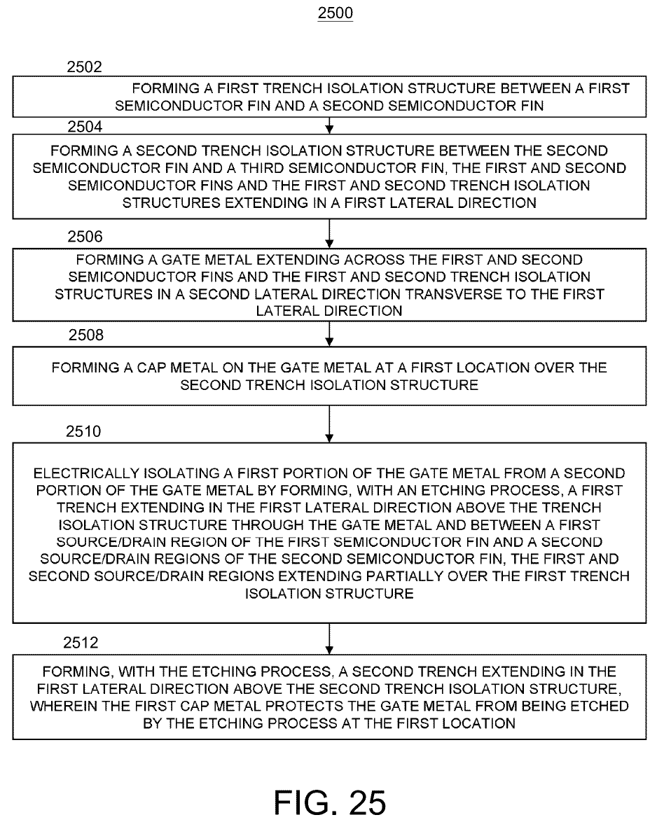

FIG. 25 is a flow diagram of a method 2500 for forming an integrated circuit, in accordance with some embodiments. The method 2500 can utilize the structures, processes, and systems described in relation to FIGS. 1-25. At 2502, the method 2500 includes forming a first isolation structure between a first semiconductor fin and a second semiconductor fin. One example of first and second semiconductor fins are the semiconductor fins 108a and 108b of FIG. 2B. At 2504, the method 2500 includes forming a second isolation structure between the second semiconductor fin and a third semiconductor fin, the first and second semiconductor fins and the first and second isolation structures extending in a first lateral direction. One example of first and second isolation structures are the isolation structures 112 of FIG. 2B. At 2506, the method 2500 includes depositing a gate metal extending across the first and second semiconductor fins and the first and second isolation structures in a second lateral direction transverse to the first lateral direction. One example of a gate metal is the gate metal 148 of FIGS. 6A-6D. At 2508, the method 2500 includes depositing a cap feature on the gate metal at a first location over the second isolation structure. One example of a cap feature is the cap feature 160 of FIG. 9B. At 2510, the method 2500 includes electrically isolating a first portion of the gate metal from a second portion of the gate metal by forming, with an etching process, a first trench extending in the first lateral direction above the isolation structure through the gate metal and between a first source/drain region of the first semiconductor fin and a second source/drain region of the second semiconductor fin, first and second source/drain regions extending partially over the first isolation structure. One example of a first trench is the trench 166 of FIG. 14B. One example of second source/drain regions of the source/drain regions 136a and 136b of FIG. 14A. At 2512, the method 2500 includes forming, with the etching process, a second trench extending in the first lateral direction above the second isolation structure, wherein the first cap feature protects the gate metal from being etched by the etching process at the first location. One example of a second trench is the trench 166 above the cap feature 160 of FIG. 14B.

Embodiments of the present disclosure enable formation of an array of transistors including efficiently and effectively isolating the source/drain regions of adjacent transistors and isolating the gate electrodes of adjacent transistors. After formation of the source/drain regions and gate metals of the transistors, dielectric isolation structures are formed to separate adjacent portions of the gate metal (at gate cut locations) and to separate adjacent source/drain regions of different transistors (at source/drain cut locations) in a same cut/isolation process. Prior to this process, a cap feature is formed on the gate metal at selected locations where the gate is not to be cut. After formation of the cap feature, the cut/isolation process includes an etching process that etches the source/drain regions and gate metals at desired locations, while the gate metal is protected at other locations by the cap feature. The cut/isolation process includes forming the dielectric isolation structures that extend through the cut locations. This enables further downward scaling of the distance between adjacent active regions. Wafer yields and device performances are improved with a simple and effective process.

The formation and treatment of the first and second gate spacer sublayers results in high resistance to subsequent etching processes. The result is that portions of the gate spacer layer are not undesirably removed. This further prevents leakage and short circuits between subsequently formed gate metals and source/drain contact metals. This also reduces the capacitance between the gate metals and the source/drain contact metals. Accordingly, transistors are properly formed and have improved switching speed and other electrical characteristics. Integrated circuits that include the transistors have improved functionality. Wafer yields are increased and the performance of electronic devices in which the integrated circuits are installed is improved.

In some embodiments, a method includes forming a first semiconductor fin extending in a first lateral direction, forming a second semiconductor fin extending in the first lateral direction, and forming a first isolation structure between the first semiconductor fin and the second semiconductor. The method includes forming a gate metal extending in a second lateral direction transverse to the first lateral direction across the first semiconductor fin, the second semiconductor fin, and the first isolation structure, forming a first source/drain region of a first transistor in the first fin extending partially over the first isolation structure, and forming a second source/drain region of a second transistor in the second fin extending partially over the first isolation structure. The method includes forming a cap feature in a recess in a top surface of the gate metal and forming a dielectric isolation structure extending in the first lateral direction between the first and second source/drain regions and between and second portions of the gate metal. The dielectric isolation structure electrically isolates the first and second source/drain regions from each other and electrically isolates the first and second portions of the first gate metal from each other.

In some embodiments, a method includes forming a first isolation structure between a first semiconductor fin and a second semiconductor fin and forming a second isolation structure between the second semiconductor fin and a third semiconductor fin. The first and second semiconductor fins and the first and second isolation structures extend in a first lateral direction. The method includes forming a gate metal extending across the first and second semiconductor fins and the first and second isolation structures in a second lateral direction transverse to the first lateral direction and forming a cap feature on the gate metal at a first location over the second isolation structure. The method includes electrically isolating a first portion of the gate metal from a second portion of the gate metal by forming, with an etching process, a first trench extending in the first lateral direction above the isolation structure through the gate metal and between a first source/drain region of the first semiconductor fin and a second source/drain region of the second semiconductor fin. The first and second source/drain regions extending partially over the first isolation structure. The method includes forming, with the etching process, a second trench extending in the first lateral direction above the second isolation structure. The first cap feature protects the gate metal from being etched by the etching process at the first location.

In some embodiments, a device includes a first active region extending in a first lateral direction, a second active region extending in the first lateral direction, and a third active region extending in the first lateral direction. The device includes a first isolation structure between the first active region and the second active region and a second isolation structure between the second active region and the third active region. The device includes a gate metal extending in a second lateral direction transverse to the first lateral direction across the first active region, the second active region, the third active region, the first isolation structure, and the first isolation structure. The device includes a first transistor in the first active region and including a first source/drain region extending partially over the first isolation structure and a second transistor in the second active region and including a second source/drain region extending partially over the first isolation structure. The device includes a cap feature in a recess in a top surface of the gate metal above the first isolation structure and a first dielectric isolation structure extending in the first lateral direction between the first and second source/drain regions and between first and second portions of the gate metal. The dielectric isolation structure electrically isolates the first and second portions of the gate metal from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor fin extending in a first lateral direction;
forming a second semiconductor fin extending in the first lateral direction;
depositing a first isolation structure between the first semiconductor fin and the second semiconductor fin;
depositing a gate metal extending in a second lateral direction transverse to the first lateral direction across the first semiconductor fin, the second semiconductor fin, and the first isolation structure;
growing a first source/drain region of a first transistor in the first fin extending partially over the first isolation structure;
growing a second source/drain region of a second transistor in the second fin extending partially over the first isolation structure;
depositing a cap feature in a recess in a top surface of the gate metal; and
forming a dielectric isolation structure extending in the first lateral direction between the first and second source/drain regions and between first and second portions of the gate metal, the dielectric isolation structure electrically isolating the first and second source/drain regions from each other and electrically isolating the first and second portions of the first gate metal from each other.

2. The method of claim 1, further comprising:
recessing the gate metal recessing the gate metal to form the recess therein; and
depositing the cap feature in the recess on the second portion of the gate metal.

3. The method of claim 2, further comprising:
forming a third semiconductor fin extending in the first lateral direction; and
forming a second isolation structure between the second semiconductor fin and the third semiconductor fin, wherein the recess and the cap feature are over the second isolation structure.

4. The method of claim 3, wherein the second portion of the gate metal is a joint gate electrode of the second transistor and a third transistor of the third semiconductor fin.

5. The method of claim 1, further comprising:
forming a first mask structure over the first gate metal, the first and second semiconductor fins, and the first and second source/drain regions;
forming the recess in the first gate metal by forming a first trench through the first mask structure; and
forming the cap feature by selectively depositing the cap feature in the indent of the first gate metal.

6. The method of claim 5, further comprising:
forming a second mask structure over the first gate metal, the first and second semiconductor fins, the first isolation structure, and the first and second source/drain regions;
patterning the mask structure to form a second trench and a third trench, the second trench extending in the first lateral direction over the first isolation structure, the third trench exposing the cap feature; and
forming the dielectric isolation structure in the second trench.

7. The method of claim 6, wherein forming the second trench includes removing, with an etching process, a portion of the first source/drain region, the second source/drain region, and the first gate metal.

8. The method of claim 7, wherein the cap feature stops the third trench from extending into the first gate metal.

9. The method of claim 6, wherein forming the dielectric isolation structure includes:
forming a first dielectric layer lining sidewalls of the second trench; and
depositing a second dielectric layer in the second trench.

10. The method of claim 6, wherein the third trench extends between a third source/drain region of a third transistor and a fourth source/drain region of a fourth transistor.

11. A method, comprising:
forming a first isolation structure between a first semiconductor fin and a second semiconductor fin;
forming a second isolation structure between the second semiconductor fin and a third semiconductor fin, the first and second semiconductor fins and the first and second isolation structures extending in a first lateral direction;
depositing a gate metal extending across the first and second semiconductor fins and the first and second isolation structures in a second lateral direction different from the first lateral direction;
depositing a cap feature on the gate metal at a first location over the second isolation structure;
electrically isolating a first portion of the gate metal from a second portion of the gate metal by forming, with an etching process, a first trench extending in the first lateral direction above the isolation structure through the gate metal and between a first source/drain region of the first semiconductor fin and a second source/drain region of the second semiconductor fin, the first and second source/drain regions extending partially over the first isolation structure; and
forming, with the etching process, a second trench extending in the first lateral direction above the second isolation structure, wherein the first cap feature protects the gate metal from being etched by the etching process at the first location.

12. The method of claim 11, wherein forming the first trench includes removing a least a portion of the first source/drain region and at least a portion of the second source/drain region.

13. The method of claim 11, further comprising forming a first dielectric isolation structure in the first trench extending between the first and second portions of the gate metal and between the first and second source/drain regions.

14. The method of claim 11, further comprising forming a second dielectric isolation structure in the second trench extending between a third source/drain region of the first semiconductor fin and a fourth source/drain region of the third semiconductor fin.

15. The method of claim 11, wherein forming the cap feature includes:
exposing the gate metal at the first location; and
performing a deposition process that selectively grows the cap feature on the gate metal but not on dielectric surfaces.

16. The method of claim 11, wherein the first dielectric isolation structure is laterally separated from the first source/drain region by an interlevel dielectric layer.

17. A device, comprising:
a first active region extending in a first lateral direction;
a second active region extending in the first lateral direction;
a third active region extending in the first lateral direction;
a first isolation structure between the first active region and the second active region;
a second isolation structure between the second active region and the third active region;
a gate metal extending in a second lateral direction different from the first lateral direction across the first active region, the second active region, the third active region, the first isolation structure, and the first isolation structure;
a first transistor in the first active region and including a first source/drain region extending partially over the first isolation structure;
a second transistor in the second active region and including a second source/drain region extending partially over the first isolation structure;
a cap feature in a recess in a top surface of the gate metal above the first isolation structure; and
a first dielectric isolation structure extending in the first lateral direction between the first and second source/drain regions and between first and second portions of the gate metal, the dielectric isolation structure electrically isolating the first and second portions of the gate metal from each other.

18. The device of claim 17, wherein the cap feature is a cap feature.

19. The device of claim 17, further comprising:
a third transistor in the third active region and including a third source/drain region;
a fourth transistor in the second active region and including a fourth source/drain region; and
a second dielectric structure extending in the first lateral direction between the third and fourth source/drain regions and abutting a side surface of gate metal adjacent to the cap feature.

20. The device of claim 17, wherein the cap feature includes ruthenium and the gate metal includes tungsten.
